(19) United States
(12) Patent Application Publication
(10) Pub. No.: US 2019/0058330 A1
(43) Pub. Date: Feb. 21, 2019

(54) ELECTRIC POWER CONTROL APPARATUS, ELECTRIC POWER CONTROL METHOD, AND PROGRAM

(71) Applicant: NEC Corporation, Tokyo (JP)

(72) Inventors: Noriaki KOBAYASHI, Tokyo (JP); Hidekazu KIMURA, Tokyo (JP)

(73) Assignee: NEC Corporation, Tokyo (JP)

(21) Appl. No.: 16/089,030

(22) PCT Filed: Mar. 22, 2017
(86) PCT No.: PCT/JP2017/011355

§ 371 Date: Sep. 27, 2018

(30) Foreign Application Priority Data
Mar. 31, 2016 (JP) 2016-072087

(51) Int. Cl. H02J 3/38; G06Q 50/06; H02J 13/00; H02J 3/00; G05F 1/66; G01R 19/165

(52) U.S. Cl. CPC H02J 3/382; G06Q 50/06; H02J 13/0079; G01R 21/133; G05F 1/66; G01R 19/16547; H02J 2003/007; H02J 3/008

(57) ABSTRACT

An electric power control apparatus (100) includes an electric power procurement information deciding unit (110) that decides electric power procurement information using a predicted electric power generation output of an electric power generating apparatus and control instruction information which includes a period in which an output of the electric power generating apparatus is controlled and an upper limit output value thereof, the electric power procurement information indicating procured electric power or an amount of procured electric power acquired from a difference between the predicted electric power generation output during the period and the upper limit output value, a desired purchase information collecting unit (120) that transmits sales information related to the procured electric power or the amount of procured electric power in the electric power procurement information to a terminal of a consumer, and collects desired purchase information indicating desired electric power for purchase or a desired amount of electric power for purchase with respect to the procured electric power or the amount of procured electric power in the electric power procurement information, and a comparison data output unit (130) that outputs comparison data for comparing the electric power procurement information with the desired purchase information.

### TECHNICAL FIELD

The present invention relates to an electric power control apparatus, an electric power control method, and a program.

### BACKGROUND ART

Electric power generating apparatuses that generate electric power using renewable energy are known, such as a solar power generating apparatus and a wind power generating apparatus. The number of such electric power generating apparatuses connected to an electric power system has increased, and one factor of such an increase is the start of a feed-in tariff (FIT) that obligates electric power companies to purchase electric power generated by such electric power generating apparatuses at a fixed price.

Patent Documents 1 to 3 disclose technologies related to a system that controls supply and demand of electric power.

Patent Document 1 discloses the following technology. That is, disclosed is a method of (A) collecting electric power load data of a large number of electric power consumers, each including an on-site electric power generator, (B) grouping the large number of electric power consumers with reference to the collected electric power load data such that peak shaving is performed on the total demanded electric power, and (C) a resource aggregator, as a representative of the grouped electric power consumers, supplying electric power purchased from an independent power producer to each electric power consumer while monitoring a change in the electric power load of each electric power consumer at all times.

Patent Document 2 discloses the following technology. That is, disclosed is an electric power trade broker system that is a network system configured with a broker terminal, an electric power buyer terminal, at least one electric power seller terminal, and a network. In the electric power trade broker system, (A) the electric power seller terminal transmits desired electric-power-sales information, (B) a processing unit of the broker terminal receives the desired electric-power-sales information through the network and stores the desired electric-power-sales information in a storage unit, (C) the electric power buyer terminal transmits desired electric-power-purchase information, (D) the processing unit of the broker terminal receives the desired electric-power-purchase information through the network and stores the desired electric-power-purchase information in the storage unit, (E) a transportation-related cost is calculated on the basis of the desired electric power sales information and the desired electric-power-purchase information, and (F) the electric power buyer terminal receives the desired electric power sales information and the transportation-related cost through the network.

Patent Document 3 discloses the following system. That is, disclosed is a system in which an economic load distribution adjusting apparatus (A) acquires an optimal hydropower generation amount, an optimal demand amount, and a unit price of generated electric power from a supply-demand planning apparatus and (B) acquires a planned hydropower generation amount planned by a water-level planning apparatus; and (C) a charging control apparatus acquires a planned demand amount, (D) the water-level planning apparatus is caused to replan the hydropower generation amount by decreasing the price of electric power at the time when the planned generated hydropower exceeds the optimal power generation amount, and (E) a stored-water-temperature control apparatus is caused to replan the demand amount by increasing the unit price of electric power at the time when the planned demand amount exceeds the optimal demand amount.

Patent Document 4 discloses a system that maintains market liquidity by appropriately controlling a price provided by a market maker in a market of a market making scheme. The system includes (A) a price change and requotation determination processing unit that determines whether or not the total amount of executed quantities at the same price reaches a preset amount for price change timing decision, (B) a requoted price decision processing unit that increases finally quoted offer and bid prices by a preset price change amount at the time of offer execution and decreases the requoted offer and bid prices by the price change amount at the time of bid execution in a case where it is determined that the total amount reaches the amount for price change timing decision, and (C) a quotation information output processing unit that outputs decided offer and bid prices to a PTS market system.

### RELATED DOCUMENT

### Patent Document

[Patent Document 1] Japanese Patent Application Publication No. 2004-007856

[Patent Document 2] Japanese Patent Application Publication No. 2001-243358

[Patent Document 3] International Publication No. 2013-084300

[Patent Document 4] Japanese Patent Application Publication No. 2010-039894

### SUMMARY OF THE INVENTION

### Technical Problem

The magnitude of electric power output from the above electric power generating apparatus that uses renewable energy may fluctuate due to the effects of natural environments (for example, sunlight and wind). For example, in a case where the electric power generating apparatus is a solar power generating apparatus, the output electric power value increases from the morning until noon to reach its peak at noon and then, decreases as the sun sets. When the supply-demand balance of electric power is broken due to such a fluctuating output of electric power, various adverse effects may occur. For example, the electric power from the electric power generating apparatus may cause problems such that electric power supply becomes excessive with respect to electric power demand, or the voltage or the frequency of the electric power system is increased.

In order to avoid the occurrence of such adverse effects, an operator who manages and operates the electric power system stabilizes the balance of electric power of the electric power system by providing an instruction to control an unstable output of the electric power generating apparatus (that is, to control the amount of output fluctuation of the electric power generating apparatus). Note that in a case where no measures are taken with respect to the output control, the controlled electric power of the electric power generating apparatus is wasted without being used. Thus, a system that effectively uses such electric power is desired. However, such a system is not proposed in the technologies of the above patent documents.

An object of the invention is to provide a technology for effectively using electric power of an electric power generating apparatus that uses natural energy.

### Solution to Problem

According to the invention, there is provided an electric power control apparatus including an electric power procurement information deciding unit that decides electric power procurement information using a predicted electric power generation output of an electric power generating apparatus and control instruction information which includes a period in which an output of the electric power generating apparatus is controlled and an upper limit output value thereof, the electric power procurement information indicating procured electric power or an amount of procured electric power acquired from a difference between the predicted electric power generation output during the period and the upper limit output value, a desired purchase information collecting unit that transmits sales information related to the procured electric power or the amount of procured electric power in the electric power procurement information to a terminal of a consumer, and collects desired purchase information indicating desired electric power for purchase or a desired amount of electric power for purchase with respect to the procured electric power or the amount of procured electric power in the electric power procurement information, and a comparison data output unit that outputs comparison data for comparing the electric power procurement information with the desired purchase information.

According to the invention, there is provided an electric power control method executed by a computer, including deciding electric power procurement information using a predicted electric power generation output of an electric power generating apparatus and control instruction information which includes a period in which an output of the electric power generating apparatus is controlled and an upper limit output value thereof, the electric power procurement information indicating procured electric power or an amount of procured electric power acquired from a difference between the predicted electric power generation output during the period and the upper limit output value, transmitting sales information related to the procured electric power or the amount of procured electric power in the electric power procurement information to a terminal of a consumer, and collecting desired purchase information indicating desired electric power for purchase or a desired amount of electric power for purchase with respect to the procured electric power or the amount of procured electric power in the electric power procurement information, and outputting comparison data for comparing the electric power procurement information with the desired purchase information.

According to the invention, there is provided a program causing a computer to function as an electric power procurement information deciding unit that decides electric power procurement information using a predicted electric power generation output of an electric power generating apparatus and control instruction information which includes a period in which an output of the electric power generating apparatus is controlled and an upper limit output value thereof, the electric power procurement information indicating procured electric power or an amount of procured electric power acquired from a difference between the predicted electric power generation output during the period and the upper limit output value, a desired purchase information collecting unit that transmits sales information related to the procured electric power or the amount of procured electric power in the electric power procurement information to a terminal of a consumer, and collects desired purchase information indicating desired electric power for purchase or a desired amount of electric power for purchase with respect to the procured electric power or the amount of procured electric power in the electric power procurement information, and a comparison data output unit that outputs comparison data for comparing the electric power procurement information with the desired purchase information.

### Advantageous Effects of Invention

According to the invention, it is possible to effectively use electric power of an electric power generating apparatus that uses natural energy.

### BRIEF DESCRIPTION OF THE DRAWINGS

The above object and other objects, features, and advantages will become more apparent from the following preferable example embodiments and the attached drawings.

FIG. 1 is a block diagram illustrating a schematic configuration of an electric power control system of the invention.

FIG. 2 is a block diagram conceptually illustrating a configuration of an electric power control system according to a first example embodiment.

FIG. 3 is a diagram illustrating a hardware configuration of an electric power control apparatus of the first example embodiment.

FIG. 4 is a sequence diagram illustrating an operating example of the electric power control system of the first example embodiment.

FIG. 5 is a diagram for describing a specific flow of deciding the amount of procured electric power.

FIG. 6 is a block diagram conceptually illustrating a configuration of an electric power control system according to a second example embodiment.

FIG. 7 is a sequence diagram illustrating a first operating example of the electric power control system of the second example embodiment.

FIG. 8 is a sequence diagram illustrating a second operating example of the electric power control system of the second example embodiment.

FIG. 9 is a sequence diagram illustrating a second operating example of an electric power control system of a third example embodiment.

### DESCRIPTION OF EMBODIMENTS

Hereinafter, example embodiments of the invention will be described using the drawings. Note that the same constituents will be designated by the same reference signs in all of the drawings, and descriptions of such constituents will not be repeated. In addition, in each block diagram, each block represents a configuration of a function unit and not a configuration of a hardware unit unless otherwise specified.

### First Example Embodiment

[System Configuration]

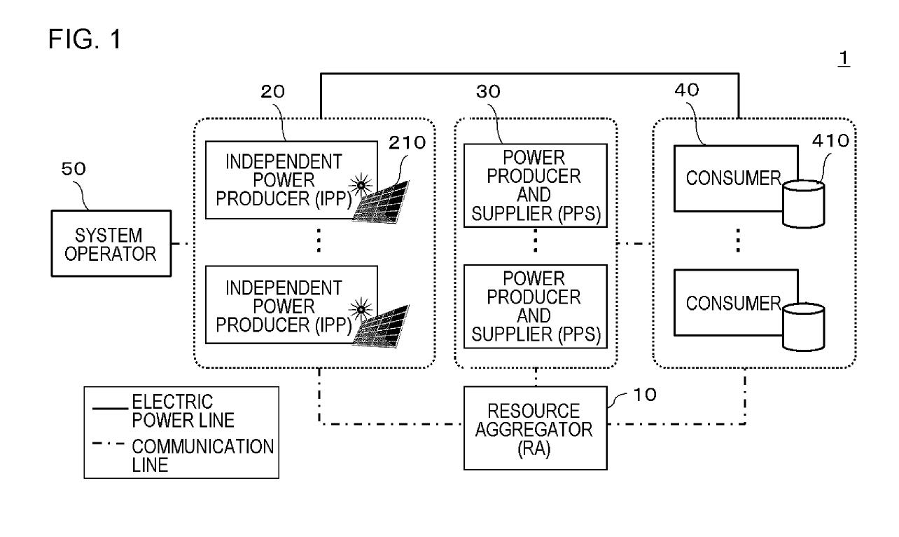

FIG. 1 is a block diagram illustrating a schematic configuration of an electric power control system 1 of the invention. The electric power control system 1 is configured to include a configuration of a resource aggregator (RA) 10, a configuration of an independent power producer (IPP) 20, a configuration of a power producer and supplier (PPS) 30, a configuration of a consumer 40, and a configuration of a system operator 50. Note that a solid line in the drawing illustrates connection by an electric power line, and a dot-dashed line in the drawing illustrates connection by a communication line.

The resource aggregator 10 provides various services for managing supply and demand of electric power by collecting information on a plurality of the independent power producers 20, information on a plurality of the power producer and suppliers 30, and information on a plurality of the consumers 40. The independent power producers 20, the power producer and suppliers 30, and the consumers 40 can use various services by signing a contract with the resource aggregator 10. The independent power producers 20 and the power producer and suppliers 30 independently sign a contract with the resource aggregator 10 for a service for effectively using electric power in a case where the output of an electric power generating apparatus 210 is controlled. In addition, the power producer and suppliers 30 signs a contract with the consumers 40 which the power producer and suppliers manage for assignment of a right of control of a load (for example, an electric power storage apparatus 410) to the resource aggregator 10 in order to use the right of control in the service.

Each independent power producer 20 has the electric power generating apparatus 210. The electric power generating apparatus 210 is an apparatus that generates electric power using natural energy such as sunlight, wind power, and geothermal heat. The independent power producers 20 supply the electric power generated by the electric power generating apparatuses 210 to the power producer and suppliers 30 directly or through the resource aggregator 10.

The power producer and suppliers 30 sign a contract related to supply and demand of electric power with the consumers 40, and supply electric power to the consumers 40 in accordance with the contract. The power producer and suppliers 30 procure the electric power to be supplied to the consumers 40 from the independent power producers 20 directly or through the resource aggregator 10.

The consumers 40 receive electric power from the power producer and suppliers 30. In addition, each consumer 40 includes the electric power storage apparatus 410 that can be remotely controlled by the resource aggregator 10. The resource aggregator 10 can remotely control the electric power storage apparatus 410 of each consumer 40 in accordance with details of a contract with the consumers 40.

The system operator 50 performs supply and demand of electric power and cross-regional operation of an electric power system. The system operator 50 is the Organization for Cross-regional Coordination of Transmission Operators in Japan. When supply and demand are tight, the system operator 50 provides measures including control of the output of the electric power generating apparatus 210 of each independent power producer 20.

The magnitude of electric power output from each electric power generating apparatus 210 described above may fluctuate due to the effects of natural environments (for example, sunlight and wind). For example, in a case where each electric power generating apparatus 210 is a solar power generating apparatus, the output electric power value increases from the morning until noon to reach its peak at noon and then, decreases as the sun sets. When the supply-demand balance of electric power is broken due to such a fluctuating output of electric power, various adverse effects may occur. For example, the electric power from each electric power generating apparatus 210 may cause problems such that electric power supply becomes excessive with respect to electric power demand, or the voltage or the frequency of the electric power system is increased.

In order to avoid the occurrence of such adverse effects, the system operator 50 stabilizes the balance of electric power of the electric power system by providing an instruction to control unstable output of each electric power generating apparatus 210 (that is, to control the amount of output fluctuation of each electric power generating apparatus 210). Note that in a case where no measures are taken with respect to the output control, the controlled electric power of each electric power generating apparatus 210 is wasted without being used. Thus, a system that effectively uses such electric power is desired. Hereinafter, a specific configuration for effectively using such electric power will be described.

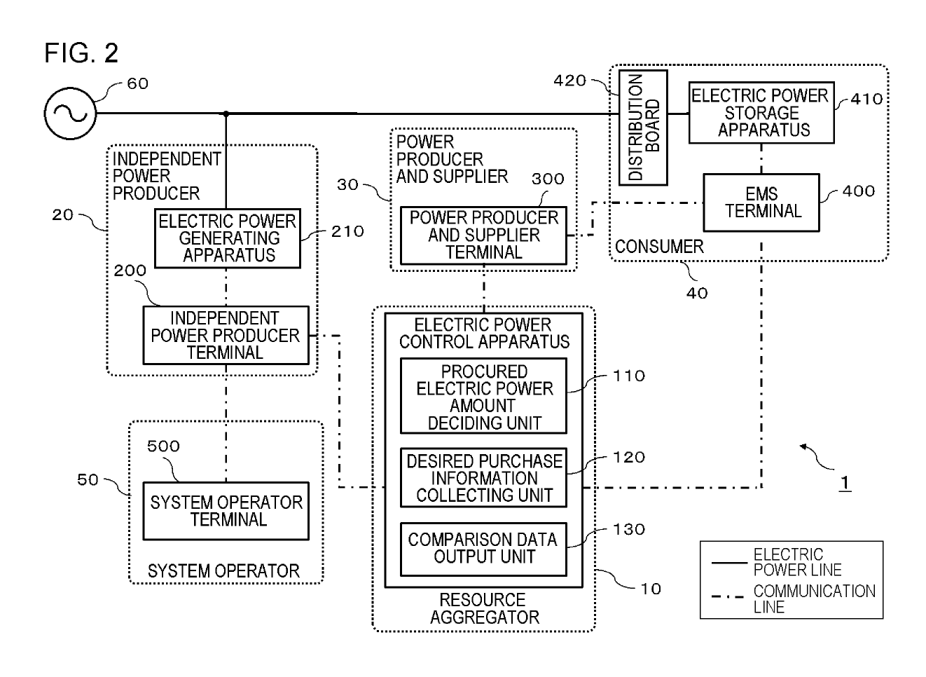

FIG. 2 is a block diagram conceptually illustrating a configuration of the electric power control system 1 according to a first example embodiment. Note that a solid line in the drawing illustrates connection by an electric power line, and a dot-dashed line in the drawing illustrates connection by a communication line.

[Configuration of System Operator 50]

As illustrated in FIG. 2, the system operator 50 includes a system operator terminal 500. The system operator terminal 500 monitors a balance between supply and demand of electric power in an electric power system 60. In addition, the system operator terminal 500 predicts the possibility of breakage of the supply-demand balance of electric power in the electric power system 60. In a case where the possibility of breakage of the supply-demand balance of electric power is predicted to be high, the system operator terminal 500 transmits information (control instruction information) related to an instruction to control the output of the electric power generating apparatuses 210 to each independent power producer (IPP) terminal 200.

The control instruction information includes a period (hereinafter, referred to as a control period) in which the output of each electric power generating apparatus 210 is controlled, and an upper limit output value of electric power during the period. The system operator 50 decides the control period to be a period in which the possibility of excessive supply of electric power is high (for example, a period of 11:00 to 15:00 in which an electric power generation peak of solar power generation appears), and inputs the decided period into the system operator terminal 500. In addition, the system operator 50 inputs the upper limit output value during the period into the system operator terminal 500. The upper limit output value may be represented as a ratio with respect to the rated output of each electric power generating apparatus 210, or may be represented as a value of electric power. The system operator terminal 500 transmits the control instruction information including the input control period and upper limit output value to the IPP terminal 200 of each independent power producer 20. Note that the control instruction information may be the same information for all of the independent power producers 20, or may be different information for each independent power producer 20.

[Configuration of Independent Power Producer 20]

As illustrated in FIG. 2, each independent power producer 20 includes the IPP terminal 200 and the electric power generating apparatus 210. As described above, the electric power generating apparatus 210 is an apparatus that generates electric power using natural energy such as sunlight, wind power, and geothermal heat. The IPP terminal 200 has a function of controlling an output from the electric power generating apparatus 210 to the electric power system 60. In addition, the IPP terminal 200 communicates with an electric power control apparatus 100 of the resource aggregator 10 or the system operator terminal 500 of the system operator 50 described later, and transmits and receives information related to electric power control and the like. Specifically, when the IPP terminal 200 receives the control instruction information from the system operator terminal 500, the IPP terminal 200 transmits the information to the electric power control apparatus 100. At this point, the IPP terminal 200 also transmits data for predicting electric power that can be generated by the electric power generating apparatus 210 during the control period (electric power generation prediction data that indicates a predicted electric power generation output (electric power at each time during the control period, or the amount of electric power during the control period) of the electric power generating apparatus 210 during the control period). The electric power generation prediction data is, for example, data that indicates a temporal change in a prediction value of electric power that can be generated by the electric power generating apparatus 210, or data that indicates a probability distribution of electric power that can be generated by the electric power generating apparatus 210 at each time. Note that the control instruction information may be directly transmitted to the electric power control apparatus 100 of the resource aggregator 10 from the system operator terminal 500 of the system operator 50 without passing through the IPP terminal 200. In this case, the IPP terminal 200 need not transmit the control instruction information to the electric power control apparatus 100. In a case where the electric power control apparatus 100 can access past electric power generation record data for each electric power generating apparatus 210 (for example, the electric power generation record data is stored in the electric power control apparatus 100 or other apparatuses), the IPP terminal 200 need not output the electric power generation prediction data. In this case, the electric power control apparatus 100 calculates the electric power generation prediction data for each electric power generating apparatus 210 using the past electric power generation record data for each electric power generating apparatus 210.

[Configuration of Electric Power Producer and Supplier 30]

As illustrated in FIG. 2, each power producer and supplier 30 includes a power producer and supplier (PPS) terminal 300. The PPS terminal 300 communicates with the electric power control apparatus 100 of the resource aggregator 10 or an EMS terminal 400 of each consumer 40 described later, and transmits and receives information related to electric power control and the like. When the PPS terminal 300 receives sales information of electric power, described later, from the electric power control apparatus 100, the PPS terminal 300 transmits the sales information to a terminal (for example, the EMS terminal 400) of each consumer 40 under management. In addition, the PPS terminal 300 receives desired purchase information that indicates desired electric power for purchase or a desired amount of electric power for purchase at each time as a response to the sales information from the EMS terminal 400 of each consumer 40. The PPS terminal 300 totalizes the desired purchase information received from the EMS terminal 400 of each consumer 40 and transmits the totalized desired purchase information to the electric power control apparatus 100. Note that the sales information and the desired purchase information may be directly transmitted to the EMS terminal 400 of each consumer 40 from the electric power control apparatus 100 of the resource aggregator 10 without passing through the PPS terminal 300. In this case, the PPS terminal 300 need not transmit the sales information and the desired purchase information to each EMS terminal 400.

[Configuration of Consumer 40]

As illustrated in FIG. 2, each consumer 40 includes the EMS terminal 400, the electric power storage apparatus 410, and a distribution board 420. The EMS terminal 400 communicates with the PPS terminal 300 and the electric power control apparatus 100, and, for example, adjusts supply and demand of electric power and controls the electric power storage apparatus 410. The electric power storage apparatus 410 is an apparatus that stores electric power supplied through the electric power system 60. The distribution board 420 has a function of, for example, monitoring and controlling electric power that is supplied to the facility of the consumer 40 through the electric power system 60.

[Configuration of Resource Aggregator 10]

As illustrated in FIG. 2, the resource aggregator 10 includes the electric power control apparatus 100. The electric power control apparatus 100 of the present example embodiment includes an electric power procurement information deciding unit 110, a desired purchase information collecting unit 120, and a comparison data output unit 130.

The electric power procurement information deciding unit 110 decides information (hereinafter, referred to as electric power procurement information) that indicates electric power or the amount of electric power to be procured from the electric power generating apparatus 210 of each independent power producer 20. Specifically, from the terminal 200 of each independent power producer 20, the electric power procurement information deciding unit 110 receives the electric power generation prediction data of the electric power generating apparatus 210 of each independent power producer 20, and the information (control instruction information) related to the output control instruction notified to each independent power producer 20. The electric power procurement information deciding unit 110 decides electric power (hereinafter, referred to as procured electric power) to be controlled at each time during the control period, or the amount of electric power (hereinafter, referred to as the amount of procured electric power) to be controlled in each electric power generating apparatus 210 during the control period, using the electric power generation prediction data (predicted electric power generation output) and the control instruction information. While a specific flow will be described later, the electric power procurement information deciding unit 110 may calculate electric power or the amount of electric power to be controlled in each electric power generating apparatus 210 as follows. First, the electric power procurement information deciding unit 110 decides the predicted generated electric power of each electric power generating apparatus 210 at each time using the electric power generation prediction data received from each IPP terminal 200. Then, the electric power procurement information deciding unit 110 sets the procured electric power to be the difference between the predicted generated electric power and the upper limit output value during the control period. The amount of procured electric power during the control period can be calculated by integrating the procured electric power with respect to time.

The desired purchase information collecting unit 120 transmits the sales information related to the procured electric power or the amount of procured electric power indicated by the electric power procurement information to the terminal (for example, the energy management system (EMS) terminal 400) of each consumer 40. As one example, the desired purchase information collecting unit 120 transmits the sales information to the EMS terminal 400 of each consumer 40 through the PPS terminal 300 of each power producer and supplier 30 who manages supply and demand of electric power of each consumer 40. As another example, the desired purchase information collecting unit 120 may directly transmit the sales information to each EMS terminal 400. Then, each EMS terminal 400 determines whether or not to purchase the procured electric power using the received sales information. For example, each EMS terminal 400 determines whether or not purchasing the electric power is advantageous for the consumer 40 on the basis of the unit price of the procured electric power included in the sales information. In the case of purchasing the procured electric power, each EMS terminal 400 decides the amount of electric power for purchase (a desired amount of electric power for purchase) and the electric power value (desired electric power for purchase) at each time in the case of receiving the desired amount of electric power for purchase, using the current electric power demand of the consumer 40, the state of charge (SOC) of the electric power storage apparatus 410, the amount of contracted electric power (breaking capacity), and the like. Each EMS terminal 400 can calculate a free capacity from the SOC of the electric power storage apparatus 410 and can decide the free capacity as the desired amount of electric power for purchase. In addition, each EMS terminal 400 can decide the desired electric power for purchase at each time (electric power at the time of charging the electric power storage apparatus 410) in a range that does not exceed the amount of contracted electric power (breaking capacity). Each EMS terminal 400 transmits the desired purchase information indicating the desired electric power for purchase and the desired amount of electric power for purchase to the desired purchase information collecting unit 120 directly or through the PPS terminal 300 of each power producer and supplier 30. The desired purchase information collecting unit 120 collects the desired purchase information from each consumer 40.

The comparison data output unit 130 outputs comparison data for comparing the electric power procurement information decided by the electric power procurement information deciding unit 110 with the desired purchase information collected by the desired purchase information collecting unit 120. The comparison data output unit 130 may output data that indicates the procured electric power or the amount of procured electric power, and the desired electric power for purchase or the desired amount of electric power for purchase, or may output data that indicates a difference value therebetween. In addition, the comparison data output unit 130 may output the comparison data through a display apparatus (not illustrated) or a printing apparatus (not illustrated) connected to the electric power control apparatus 100, or may output the comparison data as an input for each processing unit of the electric power control apparatus 100 as will be specifically described later.

### Advantageous Effect

According to the present example embodiment thus far, surplus electric power that is not used in each independent power producer 20 can be effectively used, and all of the resource aggregator 10, the independent power producers 20, the power producer and suppliers 30, and the consumers 40 can make profits. Specifically, new demands generated by transmitting the sales information causes each independent power producer 20 to be able to sell electric power that cannot be output to the electric power system 60 from the electric power generating apparatus 210 due to the control instruction from the system operator 50, and each independent power producer 20 can make profits. In addition, the electric power supplied from each independent power producer 20 in response to the new demands is surplus electric power that is originally not sold to buyers. Thus, the resource aggregator 10 and the power producer and suppliers 30 between the resource aggregator 10 and the consumers 40 can procure such electric power at a low cost price. That is, the resource aggregator 10 and the power producer and suppliers 30 can set a low price as the selling price of the electric power procured from the independent power producers 20, and thus, can make profits at a high probability by attracting buyers. In addition, the consumers 40 can have opportunities to purchase electric power at a low price.

Hereinafter, the present example embodiment will be described in detail.

[Hardware Configuration]

Each functional configuration unit of the electric power control apparatus 100 according to the invention may be implemented by hardware (for example, a hardwired electronic circuit) that implements each functional configuration unit, or may be implemented by a combination of hardware and software (for example, a combination of an electronic circuit and a program controlling the electronic circuit). Hereinafter, the implementation of each functional configuration unit of the electric power control apparatus 100 by a combination of hardware and software will be further described.

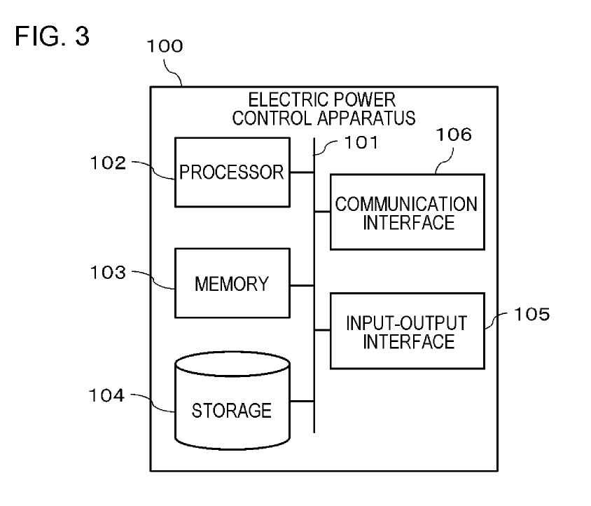

FIG. 3 is a diagram illustrating a hardware configuration of the electric power control apparatus 100 of the first example embodiment.

The electric power control apparatus 100 has a bus 101, a processor 102, a memory 103, a storage 104, an input-output interface 105, and a communication interface 106. The bus 101 is a data transfer line for transmitting and receiving data. The processor 102, the memory 103, the storage 104, the input-output interface 105, and the communication interface 106 transmit and receive data with each other through the bus 101. The method of connecting the processor 102 and the like to each other is not limited to bus connection.

The processor 102 is an operation processing apparatus such as a central processing unit (CPU) or a graphics processing unit (GPU). The memory 103 is a memory such as a random access memory (RAM) or a read-only memory (ROM). The storage 104 is a storage apparatus such as a hard disk drive (HDD), a solid state drive (SSD), or a memory card. The storage 104 may be a memory such as a RAM or a ROM.

The storage 104 stores program modules that implement the functional configuration units above (the electric power procurement information deciding unit 110, the desired purchase information collecting unit 120, and the comparison data output unit 130) of the electric power control apparatus 100. By executing each program module, the processor 102 implements each functional configuration unit corresponding to the program module. When the processor 102 executes each program module, the processor 102 may execute the program module after loading the program module into the memory 103, or may execute the program module without loading the program module into the memory 103.

The input-output interface 105 is an interface for connecting the electric power control apparatus 100 to input and output devices. For example, an input apparatus such as a mouse or a keyboard, a display apparatus such as a cathode ray tube (CRT) display or a liquid crystal display (LCD), and a touch panel in which the input apparatus and the display apparatus are integrated are connected to the input-output interface 105. A printing apparatus may also be connected to the input-output interface 105. Note that these apparatuses need not be connected to the input-output interface 105.

The communication interface 106 is an interface for connecting the electric power control apparatus 100 to various networks to communicate with external apparatuses (for example, another terminal apparatus, the display apparatus, and the printing apparatus of the resource aggregator 10) through the networks.

It should be noted that the hardware configuration of the electric power control apparatus 100 is not limited to the configuration illustrated in FIG. 3.

### Operating Example

Hereinafter, an operating example of the electric power control system 1 of the present example embodiment will be described with a specific example.

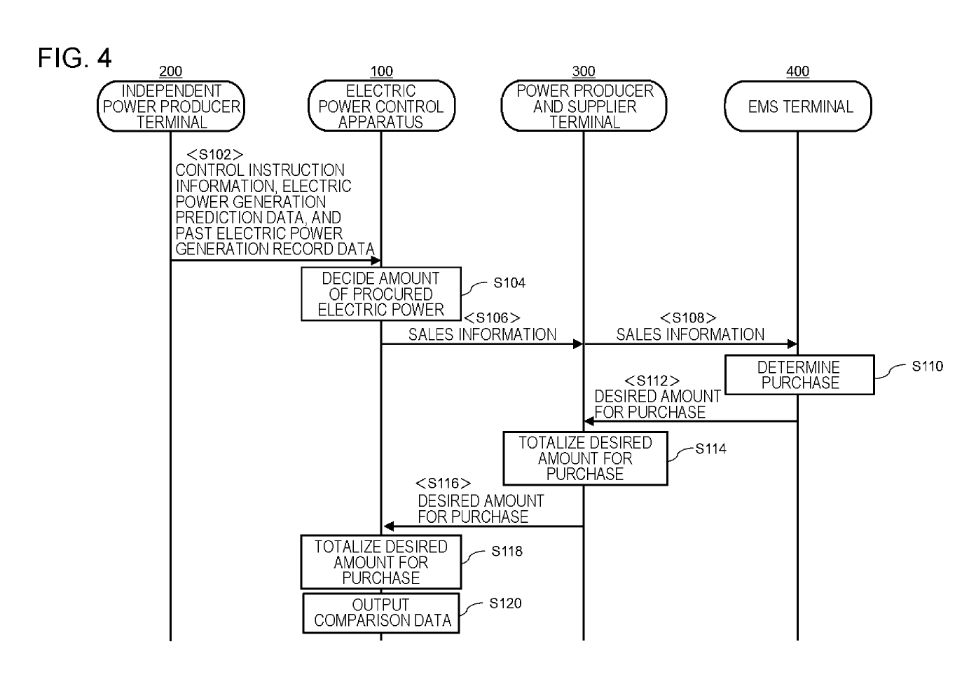

FIG. 4 is a sequence diagram illustrating the operating example of the electric power control system 1 of the first example embodiment.

First, when the IPP terminal 200 receives the control instruction information (information indicating the control period and the upper limit output value) notified from the system operator terminal 500, the IPP terminal 200 transmits the control instruction information, and the electric power generation prediction data and the past electric power generation record data of the electric power generating apparatus 210 to the electric power control apparatus 100 (S102). The electric power generation prediction data is, for example, data that indicates a temporal change in a prediction value of electric power that can be generated by the electric power generating apparatus 210, or data that indicates a probability distribution of electric power that can be generated by the electric power generating apparatus 210 at each time. The past electric power generation record data is, for example, data that indicates a probability distribution of electric power which can be derived from the past electric power generation record. Note that the derivation of the probability distribution uses different electric power generation record data for each predetermined condition (for example, a time period, a season, or weather in common).

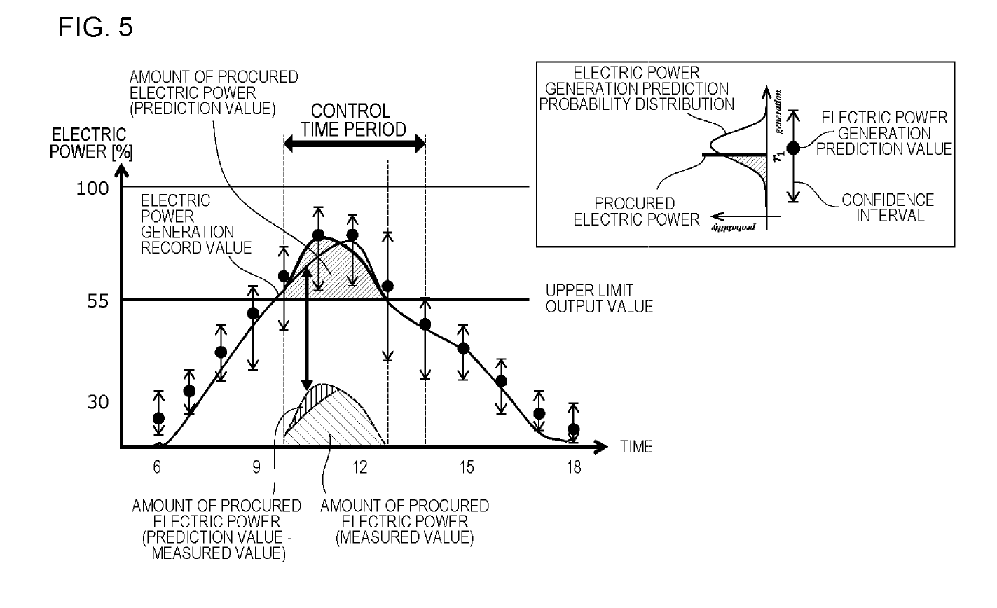

The electric power procurement information deciding unit 110 of the electric power control apparatus 100 decides the amount of electric power (the amount of procured electric power) to be procured from the electric power generating apparatus 210 using information acquired from the IPP terminal 200 (S104). A specific example of the flow of deciding the amount of procured electric power by the electric power procurement information deciding unit 110 will be described using FIG. 5. FIG. 5 is a diagram for describing a specific flow of deciding the amount of procured electric power. Note that in the following description, the electric power procurement information deciding unit 110 acquires data that indicates a temporal change in the prediction value (referred to as an electric power generation prediction value) of electric power which can be generated by the electric power generating apparatus 210.

First, the electric power procurement information deciding unit 110 acquires a probability distribution of the electric power generation prediction value (electric power generation prediction probability distribution; upper right in FIG. 5) at each time using the past electric power generation record data received from the IPP terminal 200. In the present specification, the electric power generation prediction value is defined as an electric power value (for example, a point illustrated by a black circle in FIG. 5) that corresponds to a point at which the peak of a function representing the electric power generation prediction probability distribution appears, or a point around the peak. Next, the electric power procurement information deciding unit 110 acquires a confidence interval (an interval in which the probability of the actual electric power generation value falling within the interval is higher than or equal to a predetermined value) for the electric power generation prediction probability distribution that is derived using the past electric power generation record data received from the IPP terminal 200. This confidence interval is, for example, a 95% confidence interval or a 99% confidence interval. The electric power procurement information deciding unit 110 decides the electric power value (hereinafter, referred to as an electric power value for calculation of procured electric power) at each time during the control period using the acquired confidence interval and the electric power generation prediction value at each time such that an expected value of the amount of electric power that can be procured from the electric power generating apparatus 210 is maximized. As the width of the confidence interval is increased, variation (that is, uncertainty) in the actual generated electric power value is increased, and the prediction accuracy is decreased. Conversely, as the width of the confidence interval is decreased, variation (that is, uncertainty) in the actual generated electric power value is decreased, and the prediction accuracy is increased. That is, the confidence interval can be used as an indicator that indicates the prediction accuracy for the electric power generation prediction value at each time. As the confidence interval of the electric power generation prediction probability distribution at a certain time is narrowed, an error that may occur for the electric power generation prediction value is decreased. Therefore, in a case where the width of the confidence interval of the electric power generation prediction probability distribution at a certain time is less than or equal to a predetermined threshold, the electric power procurement information deciding unit 110 employs the electric power generation prediction value at the time as the electric power value for calculation of procured electric power. The predetermined threshold may be decided by, for example, the ratio of the difference between an upper limit value and a lower limit value of the confidence interval of the electric power generation prediction probability distribution at a certain time to the electric power prediction value at the time. Specifically, the predetermined threshold may be decided as a value that represents a predetermined percentage (for example, 1 to 5%) of the difference between the upper limit value and the lower limit value of the confidence interval with respect to the electric power generation prediction value. On the other hand, in a case where the width of the confidence interval of the electric power generation prediction probability distribution at a certain time exceeds the predetermined threshold, the electric power procurement information deciding unit 110 corrects the electric power generation prediction value at the time to a smaller value, and decides the corrected value as the electric power value for calculation of procured electric power at the time. The electric power procurement information deciding unit 110 calculates the electric power value for calculation of procured electric power which is lower than the electric power generation prediction value by, for example, multiplying the electric power generation prediction value by the decided percentage (50% or the like). Alternatively, the electric power procurement information deciding unit 110 may calculate the electric power value for calculation of procured electric power in accordance with the width of the confidence interval using a function that corrects the electric power generation prediction value using the difference between the upper limit value and the lower limit value of the confidence interval as a parameter. By using such a function, the electric power value for calculation of procured electric power is set to be closer to the electric power generation prediction value as the difference between the upper limit value and the lower limit value of the confidence interval is decreased (that is, as the prediction accuracy is increased). The electric power procurement information deciding unit 110 can calculate the amount of electric power (amount of procured electric power) procured from the electric power generating apparatus 210 by integrating the difference (that is, the procured electric power) between the upper limit output value and the electric power value for calculation of procured electric power decided at each time during the control period with respect to time. The electric power procurement information deciding unit 110 calculates the amount of procured electric power of each electric power generating apparatus 210 of the independent power producers 20, and decides the total value of the amount of procured electric power as the final amount of procured electric power to be included in the electric power procurement information.

The flow described above is for illustrative purposes only, and the flow of processes of the electric power procurement information deciding unit 110 is not limited thereto. For example, the electric power procurement information deciding unit 110 may include the procured electric power at each time, or the amount of procured electric power acquired by integrating the procured electric power with respect to time, or both thereof in the electric power procurement information.

In the invention, it is important to accurately predict the amount of procured electric power. For example, in a case where the actual amount of procured electric power is below the desired amount of electric power for purchase, the resource aggregator 10 or the power producer and supplier 30 is responsible for filing the shortage of electric power. In this case, the resource aggregator 10 or the power producer and supplier terminal 300, for example, procures electric power to fill the shortage from the electric power system 60. Since the unit price of electric power of the electric power system 60 is generally higher than the unit price of electric power procured from the independent power producer 20, a loss in profit is increased as the amount of electric power to be procured is increased. In addition, in the case of not procuring electric power from the electric power system 60, the resource aggregator 10 or the PPS terminal 300 fills the shortage with electric power that is generated by its own electric power generation facility and sold to electric power companies at a feed-in tariff (FIT) price. In this case, a profit that has to be originally acquired by selling surplus electric power is decreased. According to the above method, the possibility of the actual amount of procured electric power being below the predicted amount of procured electric power can be reduced by correcting the electric power generation prediction value to be lower in a case where the prediction accuracy is low. Consequently, the amount of loss in profit of the resource aggregator 10 or the power producer and supplier 30 can be decreased.

The desired purchase information collecting unit 120 transmits information (sales information) for selling electric power procured from the electric power generating apparatus 210 of each independent power producer 20 to the terminal (EMS terminal 400) of the consumer 40 (S106). The sales information includes unit price information that indicates the unit price of electric power procured from the electric power generating apparatus 210 of each independent power producer 20. The sales information may further include information that indicates the amount of procured electric power decided in S104. Note that the present specific example illustrates an example in which the sales information is transmitted through the PPS terminal 300 of the power producer and supplier 30 having a service contract with the consumer 40. The sales information may be directly transmitted to each EMS terminal 400 without passing through the PPS terminal 300.

The PPS terminal 300 transfers the sales information to the EMS terminal 400 of the consumer 40 having a service contract with the power producer and supplier 30 (S108). At this point, the PPS terminal 300 adds a margin for the power producer and supplier 30 to the unit price of electric power included in the sales information received from the IPP terminal 200 to transmit the sales information to the EMS terminal 400 of the consumer 40.

The EMS terminal 400 determines whether or not to purchase electric power related to the sales information using the sales information received from the PPS terminal 300 (S110). Specifically, the EMS terminal 400 determines whether or not purchasing the electric power is advantageous for the consumer 40 on the basis of the unit price of electric power included in the sales information. For example, it is assumed that the whole electric power stored in the electric power storage apparatus 410 of a certain consumer 40 was charged last night at 10.3 [yen/kW]. In a case where the unit price of electric power included in the sales information is 9 [yen/kW], the EMS terminal 400 determines that the electric power having a lower unit price is to be purchased. In a case where the EMS terminal 400 decides to purchase the electric power related to the sales information, the EMS terminal 400 calculates a desired amount for purchase (the desired amount of electric power for purchase) in accordance with the current state of the consumer 40 (S112). For example, it is assumed that the current amount of purchased electric power is zero (that is, only the electric power storage apparatus 410 is operated), the maximum capacity of the electric power storage apparatus 410 is 20 [kWh], and the state of charge (SOC) of the electric power storage apparatus 410 is 50%. In this case, the EMS terminal 400 determines that a maximum of 10 [kWh] can be purchased during the control period, and calculates the desired amount of electric power for purchase to be 10 [kWh]. In addition, the EMS terminal 400 can decide the electric power value (desired electric power for purchase) at each time during the purchase of electric power in accordance with the breaking capacity. For example, in a case where the breaking capacity is 200 [V] and 50 [A], the EMS terminal 400 decides the desired electric power for purchase in a range not exceeding 10 [kW]. The EMS terminal 400 transmits the desired purchase information including the desired amount of electric power for purchase or including the desired electric power for purchase at each time and the desired amount of electric power for purchase to the PPS terminal 300 (S112).

Each PPS terminal 300 totalizes the desired amount of electric power for purchase on the basis of the desired purchase information transmitted from the EMS terminal 400 of each consumer 40 (S114). Each PPS terminal 300 transmits the totalized desired amount of electric power for purchase to the electric power control apparatus 100 (S116). These processes are not needed in a case where the desired purchase information is directly transmitted to the electric power control apparatus 100 from the EMS terminal 400.

The desired purchase information collecting unit 120 of the electric power control apparatus 100 totalizes the desired amount of electric power for purchase transmitted from each PPS terminal 300, and finalizes the final desired amount of electric power for purchase (S118). The comparison data output unit 130 outputs, for example, to the display apparatus connected to the electric power control apparatus 100, the comparison data for comparing the amount of procured electric power decided in S104 with the total of the desired amount of electric power for purchase collected in S118 (S120). An operator of the electric power control apparatus 100 can grasp the supply-demand balance between the amount of procured electric power and the desired amount of electric power for purchase on the basis of the comparison data output to the display apparatus or the like.

In a case where the amount of procured electric power is smaller than the desired amount of electric power for purchase, the operator of the electric power control apparatus 100 adjusts the desired amount of electric power for purchase to be decreased in order to align the supply-demand balance. For example, the operator of the electric power control apparatus 100 performs an input for correcting the unit price of electric power to a higher value. In accordance with this input, the desired purchase information collecting unit 120 transmits the sales information including the corrected unit price of electric power to the consumer 40 side again. Due to the increased unit price of electric power the effect of a decrease in desired amount for purchase can be expected. In addition, in a case where the amount of procured electric power is larger than the desired amount for purchase, the operator of the electric power control apparatus 100 adjusts the desired amount for purchase to be increased in order to align the supply-demand balance. For example, the operator of the electric power control apparatus 100 performs an input for correcting the unit price of electric power to a lower value. In accordance with this input, the desired purchase information collecting unit 120 transmits the sales information including the corrected unit price of electric power to the consumer 40 side again.

As illustrated in the present operating example, according to the present example embodiment, supply and demand can be generated for electric power that is originally not output and wasted due to the control instruction from the system operator 50, and the electric power can be effectively used. In addition, the data for comparing the amount of electric power (amount of procured electric power) controlled by the control instruction with the desired amount for purchase for the amount of electric power is output to the display apparatus or the like. The resource aggregator 10 can use the comparison data as reference information at the time of working out a measure for aligning the balance between the amount of procured electric power (supply) and the desired amount for purchase (demand).

It should be noted that the comparison data output from the comparison data output unit 130 can be used as an input for the desired purchase information collecting unit 120. In this case, for example, the desired purchase information collecting unit 120 acquires the comparison data including the amount of procured electric power and the desired amount of electric power for purchase, and calculates the difference value between the amount of procured electric power and the desired amount of electric power for purchase. The desired purchase information collecting unit 120 compares the calculated difference value with a predetermined reference. This reference is, for example, a predetermined threshold for determining whether or not the balance between the amount of procured electric power and the desired amount of electric power for purchase is maintained. In a case where the difference value does not satisfy the predetermined reference, the desired purchase information collecting unit 120 corrects the selling price of electric power included in the sales information. Specifically, in a case where the amount of procured electric power is smaller than the desired amount for purchase, the desired purchase information collecting unit 120 increases the unit price of electric power by a certain amount. In addition, in a case where the amount of procured electric power is larger than the desired amount for purchase, the desired purchase information collecting unit 120 decreases the unit price of electric power by a certain amount. The values of increase and decrease in the unit price of electric power are stored in advance in, for example, the storage 104. The desired purchase information collecting unit 120 transmits the sales information including the corrected selling price to the consumer 40 again. On the other hand, in a case where the difference value satisfies the predetermined reference, the balance between the amount of procured electric power and the desired amount for purchase is maintained. Thus, the desired purchase information collecting unit 120 ends receiving the desired purchase information including the desired amount of electric power for purchase. Accordingly, the balance between the amount of procured electric power (supply) indicated by the electric power procurement information and the desired amount of electric power for purchase (demand) indicated by the desired purchase information can be automatically aligned.

In addition, in the above process, in a case where the desired purchase information includes the desired electric power for purchase at each time, the desired purchase information collecting unit 120 may totalize the desired electric power for purchase at each time, and the comparison data output unit 130 may additionally (or instead) output comparison data between the procured electric power and the desired electric power for purchase at each time. By doing so, the resource aggregator 10 can work out a more detailed measure for aligning the supply-demand balance in time series.

### Second Example Embodiment

The present example embodiment is the same as the first example embodiment except for the following points.

[Functional Configuration]

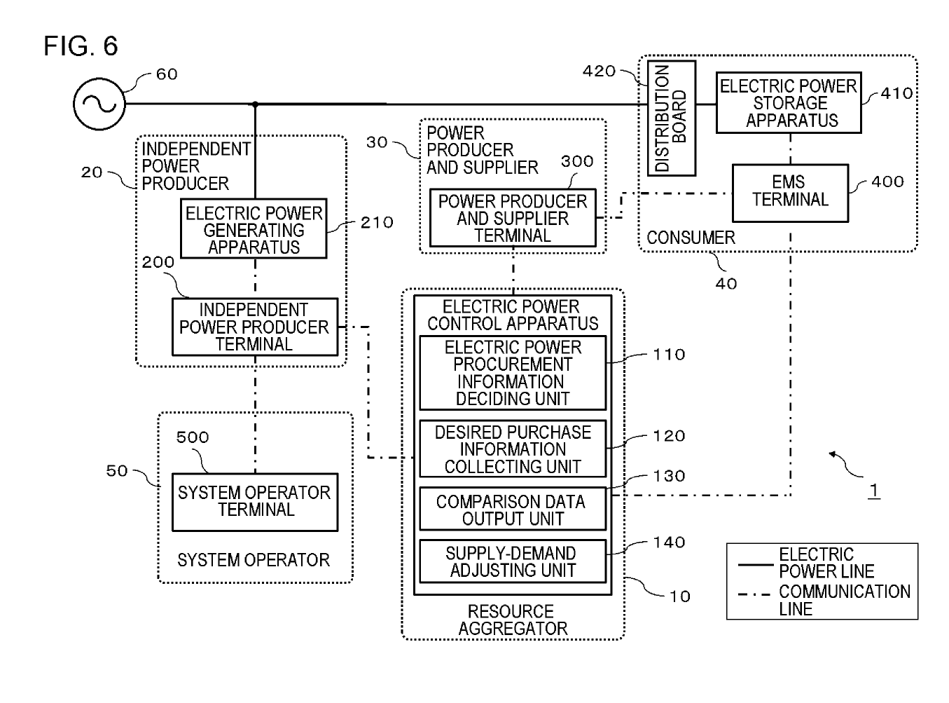

FIG. 6 is a block diagram conceptually illustrating a configuration of the electric power control system 1 according to a second example embodiment. In the present example embodiment, the resource aggregator 10 further includes a supply-demand adjusting unit 140 that requests balancing between the amount of procured electric power indicated by the electric power procurement information and the desired amount of electric power for purchase indicated by the desired purchase information, on the basis of the comparison data output from the comparison data output unit 130.

[Hardware Configuration]

The electric power control apparatus 100 of the present example embodiment has the same hardware configuration (FIG. 3) as the first example embodiment. In the present example embodiment, the storage 104 further stores a program module for implementing the function of the supply-demand adjusting unit 140. By the processor 102 executing this program module, the function of the supply-demand adjusting unit 140 is implemented.

Hereinafter, a specific operating example of the present example embodiment will be described using the drawings.

### First Operating Example

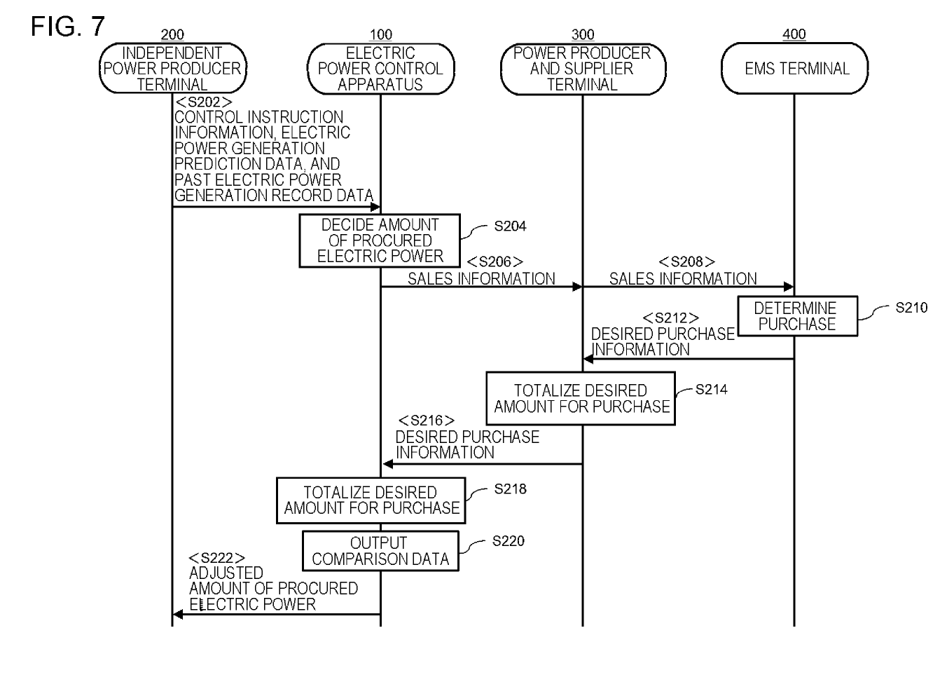

FIG. 7 is a sequence diagram illustrating a first operating example of the electric power control system 1 of the second example embodiment.

The flow of processes of S202 to S218 is the same as the flow of processes of S102 to S118 of the first example embodiment in FIG. 4. In the present operating example, the comparison data output unit 130 outputs the comparison data to the supply-demand adjusting unit 140 (S220). In the present operating example, it is assumed that comparison data indicating the amount of procured electric power is larger than the desired amount of electric power for purchase is output. In the present operating example, in a case where the amount of procured electric power is larger than the desired amount for purchase, the supply-demand adjusting unit 140 adjusts (decreases) the amount of procured electric power to the desired amount of electric power for purchase. The adjusted amount of procured electric power of each electric power generating apparatus 210 is notified to each IPP terminal 200 (S222). The IPP terminal 200 controls the output of the electric power generating apparatus 210 in accordance with the notification.

Specifically, the supply-demand adjusting unit 140 decreases the whole amount of procured electric power by adjusting the amount of procured electric power of each electric power generating apparatus 210 using attribute information of each electric power generating apparatus 210. As the attribute information of each electric power generating apparatus 210, for example, the magnitude of the amount of procured electric power of each electric power generating apparatus 210, or the prediction accuracy related to electric power generation of each electric power generating apparatus 210 can be used.

<Case where Magnitude of Amount of Procured Electric Power is Used>

Based on the magnitude of the amount of procured electric power of each electric power generating apparatus 210, the supply-demand adjusting unit 140 decides a combination of electric power generating apparatuses 210 in which the difference between the total of the amounts of procured electric power of the electric power generating apparatuses 210 and the desired amount for purchase is less than or equal to the predetermined reference. Note that there are various methods of deciding the combination of electric power generating apparatuses 210. As one example, the supply-demand adjusting unit 140 selects an electric power generating apparatus 210 as an apparatus for the combination in descending order of amount of procured electric power, and accumulates its amount of procured electric power. The supply-demand adjusting unit 140 repeats the process of selecting an electric power generating apparatus 210 as an apparatus for the combination and accumulating its amount of procured electric power until the total of the amounts of procured electric power becomes equal to the desired amount of electric power for purchase, or the difference value between the total of the amounts of procured electric power and the desired amount of electric power for purchase becomes less than or equal to the predetermined threshold. The electric power generating apparatus 210 that is not selected is excluded from apparatuses from which electric power is procured. Note that in a case where the difference value exceeds the predetermined threshold as a result of accumulating the amount of procured electric power in descending order (that is, in a case where the accumulated amount of procured electric power is larger than or equal to a reference), the supply-demand adjusting unit 140 discards the amount of procured electric power that is most recently added. Instead, the supply-demand adjusting unit 140 selects the electric power generating apparatus 210 having the largest amount of procured electric power next to the electric power generating apparatus 210 which is discarded, and accumulates its amount of procured electric power. In a case where the difference value does not become less than or equal to the predetermined threshold after repetition of such a process, the supply-demand adjusting unit 140 starts over again the process of selecting an electric power generating apparatus 210 as an apparatus for the combination and accumulating its amount of procured electric power, using the electric power generating apparatus 210 having the second largest amount of procured electric power as a starting point. As another example, in opposition to the above flow, the whole amount of procured electric power may be adjusted by excluding an electric power generating apparatus 210 from apparatuses for the combination in ascending order of the amount of procured electric power. By doing so, the balance between the amount of procured electric power and the desired amount for purchase can be easily aligned.

It should be noted that in the above process, the supply-demand adjusting unit 140 may calculate the ratio of each electric power generating apparatus 210 using the predicted electric power generation output of each electric power generating apparatus 210 instead of the amount of procured electric power of each electric power generating apparatus 210.

The supply-demand adjusting unit 140 can also adjust the whole amount of procured electric power as follows. First, the supply-demand adjusting unit 140 calculates the ratio of each electric power generating apparatus 210 using the amount of procured electric power of each electric power generating apparatus 210. The supply-demand adjusting unit 140 decides the change amount in the amount of procured electric power of each electric power generating apparatus 210, by multiplying the difference between the desired amount of electric power for purchase and the total of the amount of procured electric power of electric power generating apparatuses 210 by the calculated ratio of each electric power generating apparatus 210. As a specific example, it is considered that three electric power generating apparatuses 210 having amounts of procured electric power of 20 [kWh], 40 [kWh], and 60 [kWh] are present, and the desired amount of electric power for purchase is 90 [kWh]. In this case, the supply-demand adjusting unit 140 calculates the ratio of each electric power generating apparatus 210 to be “20 [kWh]: 40 [kWh]: 60 [kWh]=1:2:3” on the basis of the amount of procured electric power of each of the three electric power generating apparatuses 210. In addition, the supply-demand adjusting unit 140 calculates the difference between the desired amount of electric power for purchase of 90 [kWh] and the total 120 [kWh] of the procured electric power of the three electric power generating apparatuses 210 to be 30 [kWh]. The supply-demand adjusting unit 140 multiplies the calculated difference of 30 [kWh] by the ratio of each of the three electric power generating apparatuses 210 and decides the change amount in the amount of procured electric power of each of the three electric power generating apparatuses 210 as 30 [kWh]*1/6=5 [kWh], 30 [kWh]*2/6=10 [kWh], and 30 [kWh]*3/6=15 [kWh]. The supply-demand adjusting unit 140 decreases the amount of procured electric power of each of the three electric power generating apparatuses 210 by 15 [kWh], 30 [kWh], and 45 [kWh]. Accordingly, the total of the amount of procured electric power is 90 [kWh]. Thus, the balance between the amount of procured electric power and the desired amount of electric power for purchase can be easily aligned.

<Case of Using Prediction Accuracy>

Based on the level of prediction accuracy related to electric power generation of each electric power generating apparatus 210, the supply-demand adjusting unit 140 decides a combination of electric power generating apparatuses 210 in which the difference between the desired amount for purchase and the total of the amounts of procured electric power of the electric power generating apparatuses 210 is less than or equal to the predetermined reference. Note that there are various methods of deciding the combination of electric power generating apparatuses 210. As one example, the supply-demand adjusting unit 140 selects an electric power generating apparatus 210 as an apparatus for the combination in descending order of prediction accuracy, and accumulates its amount of procured electric power. The level of prediction accuracy can be decided by calculating, for example, the average value of the width of the confidence interval at each time during the control period and using the average value as a reference. The supply-demand adjusting unit 140 repeats the process of selecting an electric power generating apparatus 210 as an apparatus for the combination and accumulating its amount of procured electric power until the total of the amounts of procured electric power becomes equal to the desired amount of electric power for purchase, or the difference value between the total of the amounts of procured electric power and the desired amount of electric power for purchase becomes less than or equal to the predetermined threshold. The electric power generating apparatus 210 that is not selected is excluded from apparatuses from which electric power is procured. Note that in a case where the difference value exceeds the predetermined threshold as a result of accumulating the amount of procured electric power in descending order of prediction accuracy (that is, in a case where the accumulated amount of procured electric power that is larger than or equal to a reference), the supply-demand adjusting unit 140 discards the amount of procured electric power that is most recently added. Instead, the supply-demand adjusting unit 140 accumulates the amount of procured electric power of the electric power generating apparatus 210 having the highest prediction accuracy next to the electric power generating apparatus 210 which is discarded. In a case where the difference value does not become less than or equal to the predetermined threshold after repetition of such a process, the supply-demand adjusting unit 140 starts over again the process of selecting an electric power generating apparatus 210 as an apparatus for the combination and accumulating its amount of procured electric power, using the electric power generating apparatus 210 having the second highest prediction accuracy as a starting point. As another example, in opposition to the above flow, the whole amount of procured electric power may be adjusted by excluding an electric power generating apparatus 210 from apparatuses for the combination in ascending order of prediction accuracy. By doing so, the balance between the amount of procured electric power and the desired amount for purchase can be easily aligned.

The supply-demand adjusting unit 140 can also adjust the whole amount of procured electric power as follows. First, the supply-demand adjusting unit 140 calculates the ratio of each electric power generating apparatus 210 using the level of prediction accuracy (for example, the average value of the widths of confidence interval) of each electric power generating apparatus 210. Note that the level of prediction accuracy may be indicated by a numerical value based on another reference. The supply-demand adjusting unit 140 decides the change amount in the amount of procured electric power of each electric power generating apparatus 210, by multiplying the difference between the desired amount of electric power for purchase and the total of the amount of procured electric power of electric power generating apparatuses 210 by the calculated ratio of each electric power generating apparatus 210. As a specific example, it is considered that three electric power generating apparatuses 210 having amounts of procured electric power of 20 [kWh], 40 [kWh], and 60 [kWh] are present, and the desired amount of electric power for purchase is 90 [kWh]. In addition, it is assumed that the ratio of the average value of the width of the confidence interval of each electric power generating apparatus 210 is calculated to be 1:2:3. In this case, the supply-demand adjusting unit 140 calculates the difference between the desired amount of electric power for purchase of 90 [kWh] and the total 120 [kWh] of the procured electric power of the three electric power generating apparatuses 210 to be 30 [kWh]. The supply-demand adjusting unit 140 multiplies the calculated difference of 30 [kWh] by the ratio of each of the three electric power generating apparatuses 210 and decides the change amount in the amount of procured electric power of each of the three electric power generating apparatuses 210 as 30 [kWh]*1/6=5 [kWh], 30 [kWh]*2/6=10 [kWh], and 30 [kWh]*3/6=15 [kWh]. The supply-demand adjusting unit 140 decreases the amount of procured electric power of each of the three electric power generating apparatuses 210 by 15 [kWh], 30 [kWh], and 45 [kWh]. Accordingly, the total of the amount of procured electric power is 90 [kWh]. Thus, the balance between the amount of procured electric power and the desired amount of electric power for purchase can be easily aligned.

<Other Cases>

Alternatively, the supply-demand adjusting unit 140 may decide the electric power generating apparatus 210 from which the amount of procured electric amount is to be procured, using a priority that is set in accordance with details of the contract between the resource aggregator 10 and the independent power producer 20.

### Second Operating Example

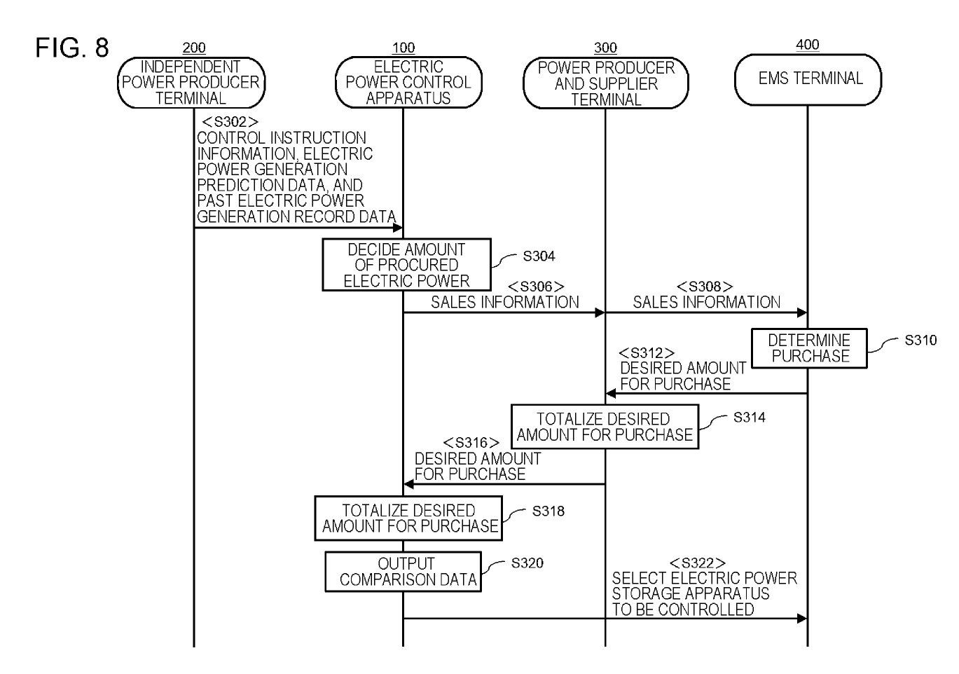

FIG. 8 is a sequence diagram illustrating a second operating example of the electric power control system 1 of the second example embodiment.

The flow of processes of S302 to S318 is the same as the flow of processes of S102 to S118 of the first example embodiment in FIG. 4. In the present operating example, the comparison data output unit 130 outputs the comparison data to the supply-demand adjusting unit 140 (S320). In the present operating example, it is assumed that comparison data indicating that the amount of procured electric power is larger than the desired amount of electric power for purchase is output. In the present operating example, in a case where the amount of procured electric power is larger than the desired amount of electric power for purchase, the supply-demand adjusting unit 140 increases the desired amount of electric power for purchase by controlling a charging operation of the electric power storage apparatus 410 of the consumer 40.

Specifically, the supply-demand adjusting unit 140 increases the desired amount for purchase as follows. First, the resource aggregator 10 generates a list of the electric power storage apparatuses 410 (that is, the electric power storage apparatuses 410 that can be controlled in order to adjust the supply-demand balance of electric power) for which the right of control is assigned at the time of signing a service contract with the power producer and supplier 30, and stores the list in advance in the storage 104 or the like. Using the list indicating the electric power storage apparatuses 410 which can be controlled in order to adjust the supply-demand balance of electric power, the supply-demand adjusting unit 140 increases the amount of scheduled charging during the control period with respect to at least one electric power storage apparatus 410 included in the list. The supply-demand adjusting unit 140 selects an electric power storage apparatus 410 to be controlled from among the electric power storage apparatuses 410 other than the electric power storage apparatus 410 of each consumer 40 who transmits the desired purchase information (S322). For example, the supply-demand adjusting unit 140 randomly selects the electric power storage apparatus 410 to be controlled. Alternatively, the supply-demand adjusting unit 140 may preferentially select an electric power storage apparatus 410 which allows forced charging subject to an increased price, or a dedicated electric power storage apparatus 410 that is only charged in a case where surplus electric power is present. Besides the electric power storage apparatus 410 of each consumer 40, the supply-demand adjusting unit 140 may additionally (or instead) control charging of an electric power storage apparatus (not illustrated) that is included in the resource aggregator 10 or the power producer and supplier 30 for filling the shortage of electric power.

More specifically, the supply-demand adjusting unit 140 decides the increase amount in the amount of scheduled charging electric power of each electric power storage apparatus 410 on the basis of the magnitude of the free capacity of the electric power storage apparatus 410.

As one example, the supply-demand adjusting unit 140 repeatedly selects an electric power storage apparatus 410 of which the amount of scheduled charging electric power is to be increased, in descending order of free capacity until the difference between the desired amount for purchase and the amount of procured electric power becomes less than or equal to the predetermined reference. An electric power storage apparatus 410 that is not selected is excluded from apparatuses of which the amount of scheduled charging electric power is controlled. The supply-demand adjusting unit 140 adds the free capacity of the selected electric power storage apparatus 410 to the desired amount for purchase. Note that in a case where the difference value exceeds the predetermined threshold as a result of adding the free capacity in descending order (that is, in a case where the added up value of amounts of electric power for purchase is larger than or equal to a reference), the supply-demand adjusting unit 140 cancels the most recent addition result. Instead, the supply-demand adjusting unit 140 selects an electric power storage apparatus 410 having the highest free capacity next to the canceled free capacity, and adds its free capacity to the amount of electric power for purchase. In a case where the difference value does not become less than or equal to the predetermined threshold after repetition of such a process, the supply-demand adjusting unit 140 starts over again the process of selecting an electric power storage apparatus 410 of which the amount of scheduled charging is to be increased, and adding its free capacity to the desired amount of electric power for purchase, using the electric power storage apparatus 410 having the second highest free capacity as a starting point. By doing so, the balance between the amount of procured electric power and the desired amount for purchase can be easily aligned.

As another example, the supply-demand adjusting unit 140 can also adjust the whole amount of procured electric power as follows. First, the supply-demand adjusting unit 140 calculates the ratio of each electric power storage apparatus 410 using the free capacity of each electric power storage apparatus 410. The supply-demand adjusting unit 140 decides the increase amount in the amount of scheduled charging of each electric power storage apparatus 410, by multiplying the difference between the desired amount of electric power for purchase and the total of the amount of procured electric power of electric power generating apparatuses 210 by the calculated ratio of each electric power storage apparatus 410. As a specific example, it is considered that three electric power generating apparatuses 210 having amounts of procured electric power of 20 [kWh], 40 [kWh], and 60 [kWh] are present, and the desired amount of electric power for purchase is 90 [kWh]. In addition, it is assumed that four electric power storage apparatuses 410 are present and have free capacities of 10 [kWh], 20 [kWh], 20 [kWh], and 30 [kWh]. In this case, the supply-demand adjusting unit 140 calculates the ratio of each electric power storage apparatus 410 to be “10 [kWh]: 20 [kWh]: 20 [kWh]: 30 [kWh]=1:2:2:3” on the basis of the free capacity of each of the four electric power storage apparatuses 410. In addition, the supply-demand adjusting unit 140 calculates the difference between the desired amount of electric power for purchase of 90 [kWh] and the total 120 [kWh] of the procured electric power of the three electric power generating apparatuses 210 to be 30 [kWh]. The supply-demand adjusting unit 140 multiplies the calculated difference of 30 [kWh] by the ratio of each of the four electric power storage apparatuses 410 and decides the increase amount in the amount of scheduled charging of each of the four electric power storage apparatuses 410 as 30 [kWh]*1/8=3.75 [kWh], 30 [kWh]*2/8=7.5 [kWh], 30 [kWh]*2/8=7.5 [kWh], and 30 [kWh]*3/8=11.25 [kWh]. The supply-demand adjusting unit 140 adds the total (=30 [kWh]) of the increase amount in the amount of scheduled charging of the four electric power generating apparatuses 210 to the desired electric power for purchase. Accordingly, the total of the desired amount of electric power for purchase is 120 [kWh]. Thus, the balance between the amount of procured electric power and the desired amount of electric power for purchase can be easily aligned.

### Third Operating Example

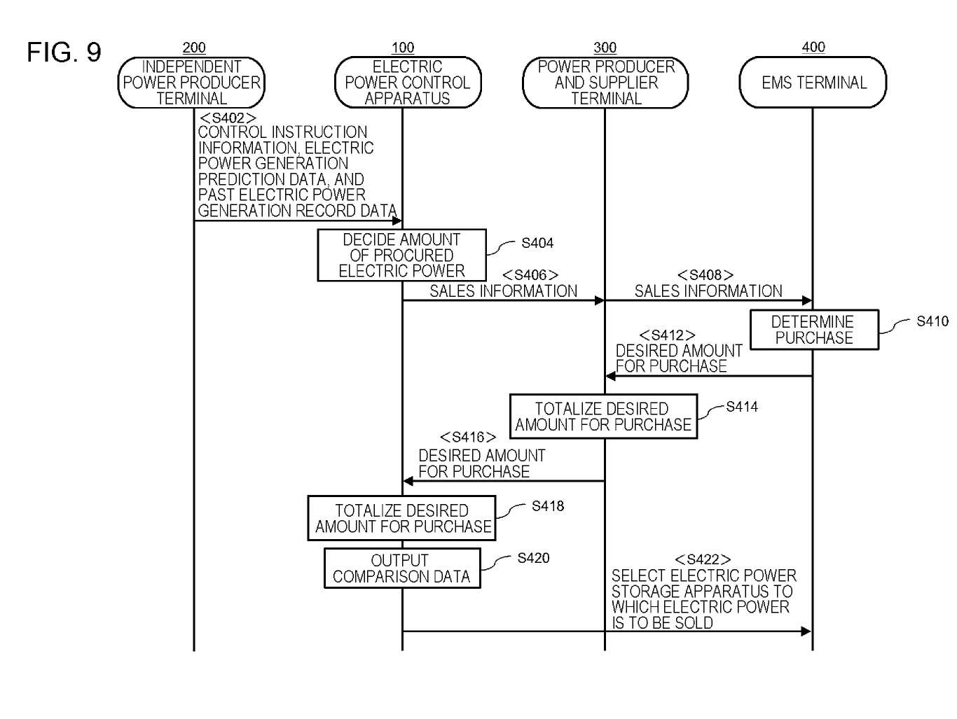

FIG. 9 is a sequence diagram illustrating a second operating example of the electric power control system 1 of a third example embodiment.

The flow of processes of S402 to S418 is the same as the flow of processes of S102 to S118 of the first example embodiment in FIG. 4. In the present operating example, the comparison data output unit 130 outputs the comparison data to the supply-demand adjusting unit 140 (S420). In the present operating example, it is assumed that comparison data indicating that the desired amount of electric power for purchase is larger than the amount of procured electric power is output. In the present operating example, in a case where the desired amount of electric power for purchase is larger than the amount of procured electric power, the supply-demand adjusting unit 140 decreases the desired amount of electric power for purchase by adjusting the amount of electric power to be sold to each consumer 40 using the attribute information of each consumer 40.

In the present operating example, the attribute information of each consumer 40 is, for example, the magnitude of the output of the electric power storage apparatus 410, the free capacity (SOC) of the electric power storage apparatus 410, the degree of deterioration (state of health (SOH), or the number of years of usage) of the electric power storage apparatus 410, a physical distance (the length of an electric power transmission line, or the like) from the electric power generating apparatus 210, the frequency of purchases of procured electric power in the past, and the like. For example, these pieces of information are managed in the storage 104. The supply-demand adjusting unit 140 preferentially and repeatedly selects an electric power storage apparatus 410 of a high output for selling electric power thereto until the desired amount of electric power for purchase becomes equal to the amount of procured electric power, or the difference value becomes less than or equal to a certain degree (S422).

Alternatively, the supply-demand adjusting unit 140 may preferentially select the electric power storage apparatus 410 of a high free capacity (that is, low SOC). Specifically, as described in the second operating example, the supply-demand adjusting unit 140 repeatedly selects an electric power storage apparatus 410 for selling electric power thereto in descending order of free capacity until the difference between the desired amount for purchase and the amount of procured electric power becomes less than or equal to the predetermined reference. Alternatively, the supply-demand adjusting unit 140 may calculate the ratio of each electric power storage apparatus 410 using the magnitude of the free capacity of each electric power storage apparatus 410, and calculate the change amount (decrease amount) in the amount of charging electric power of each electric power storage apparatus 410, by multiplying the difference value between the desired amount of electric power for purchase and the amount of procured electric power by the ratio of each electric power storage apparatus 410.

The supply-demand adjusting unit 140 may preferentially select an electric power storage apparatus 410 having a low degree of deterioration (or a small number of years of usage). Specifically, the supply-demand adjusting unit 140 selects an electric power storage apparatus 410 in ascending order of degree of deterioration (or in ascending order of number of years of usage) in the same manner as the flow of processes described in the second operating example, and accumulates the free capacity of the selected electric power storage apparatus 410. The supply-demand adjusting unit 140 repeats the process of selecting an electric power storage apparatus 410 and accumulating its free capacity until the difference between the total of the free capacities and the amount of procured electric power becomes less than or equal to the predetermined reference. Alternatively, the supply-demand adjusting unit 140 may calculate the ratio of each electric power storage apparatus 410 using the degree of deterioration (or the number of years of usage) of each electric power storage apparatus 410, and calculate the change amount (decrease amount) in the amount of charging electric power of each electric power storage apparatus 410 by multiplying the difference value between the desired amount of electric power for purchase and the amount of procured electric power by the ratio of each electric power storage apparatus 410.

The supply-demand adjusting unit 140 may preferentially select an electric power storage apparatus 410 having a short distance from the electric power generating apparatus 210, or may preferentially select an electric power storage apparatus 410 of each independent power producer 20 for which the frequency of purchases of the procured electric power in the past is small.

It should be noted that an electric power storage apparatus 410 that is not selected is excluded from apparatuses to which electric power that can be procured from the electric power generating apparatus 210 of each independent power producer 20 is sold. Accordingly, the balance between the amount of procured electric power and the desired amount of electric power for purchase can be easily aligned.

As in the first example embodiment, in a case where the desired purchase information includes the desired electric power for purchase at each time, the desired purchase information collecting unit 120 may totalize the desired electric power for purchase at each time, and the comparison data output unit 130 may additionally (or instead) output comparison data between the procured electric power and the desired electric power for purchase at each time. In this case, the supply-demand adjusting unit 140 may be operated to adjust the balance between the procured electric power at each time and the desired electric power for purchase at each time. Such an operation can eventually align the balance between the amount of procured electric power and the desired amount of electric power for purchase. In this case, in the second operating example, the supply-demand adjusting unit 140 may use the procured electric power of the electric power generating apparatus 210 and the level of chargeability of the electric power storage apparatus 410 instead of the amount of procured electric power of the electric power generating apparatus 210 and the free capacity of the electric power storage apparatus 410. The chargeability of the electric power storage apparatus 410 means, for example, a rated value or the maximum value of a charging current. In this case, the supply-demand adjusting unit 140 may decide the increase amount in the scheduled charging electric power at each time such that the balance between the charging electric power at each time and the desired electric power for purchase at each time is adjusted. Such an operation can eventually align the balance between the amount of procured electric power and the desired amount of electric power for purchase.

While example embodiments of the invention are described thus far with reference to the drawings, the example embodiments are illustrations of the invention, and various configurations other than the example embodiments can be employed.

While a plurality of steps (processes) is described in order in a plurality of sequence diagrams used in the above description, the execution order of the steps executed in each example embodiment is not limited to the described order. The order of the illustrated steps can be changed as long as no adverse effects are caused in view of the contents of the steps. Each example embodiment described above can be combined without contradiction of content.

Hereinafter, reference examples will be appended.

1. An electric power control apparatus including:

an electric power procurement information deciding unit that decides electric power procurement information using a predicted electric power generation output of an electric power generating apparatus and control instruction information which includes a period in which an output of the electric power generating apparatus is controlled and an upper limit output value thereof, the electric power procurement information indicating procured electric power or an amount of procured electric power acquired from a difference between the predicted electric power generation output during the period and the upper limit output value;

a desired purchase information collecting unit that transmits sales information related to the procured electric power or the amount of procured electric power in the electric power procurement information to a terminal of a consumer, and collects desired purchase information indicating desired electric power for purchase or a desired amount of electric power for purchase with respect to the procured electric power or the amount of procured electric power in the electric power procurement information; and

a comparison data output unit that outputs comparison data for comparing the electric power procurement information with the desired purchase information.

2. The electric power control apparatus according to 1, further including

a supply-demand adjusting unit that adjusts a balance between the procured electric power or the amount of procured electric power in the electric power procurement information and the desired electric power for purchase or the desired amount of electric power for purchase in the desired purchase information on the basis of the comparison data,

in which in a case where the procured electric power or the amount of procured electric power in the electric power procurement information is larger than the desired electric power for purchase or the desired amount of electric power for purchase in the desired purchase information, the supply-demand adjusting unit decreases the procured electric power or the amount of procured electric power in the electric power procurement information to the desired electric power for purchase or the desired amount of electric power for purchase in the desired purchase information.

3. The electric power control apparatus according to 2,

in which the supply-demand adjusting unit decreases the whole procured electric power or the whole amount of procured electric power by adjusting the procured electric power or the amount of procured electric power of each electric power generating apparatus using attribute information of each electric power generating apparatus.

4. The electric power control apparatus according to 3,

in which the supply-demand adjusting unit
calculates a ratio of each electric power generating apparatus using the predicted electric power generation output of each electric power generating apparatus, and

decides a change amount in the procured electric power or the amount of procured electric power of each electric power generating apparatus in accordance with a difference between a total of the procured electric power or a total of the amount of procured electric power and the desired electric power for purchase or the desired amount of electric power for purchase and the calculated ratio of each electric power generating apparatus.

5. The electric power control apparatus according to 3,

in which the supply-demand adjusting unit decides a combination of electric power generating apparatuses in which a difference between a total of the procured electric power or a total of the amount of procured electric power and the desired electric power for purchase or the desired amount of electric power for purchase is less than or equal to a predetermined reference, on the basis of a magnitude of the predicted electric power generation output of each electric power generating apparatus.

6. The electric power control apparatus according to 3,

in which the supply-demand adjusting unit
calculates a ratio of each electric power generating apparatus using prediction accuracy related to electric power generation of each electric power generating apparatus, and

decides a change amount in the procured electric power or the amount of procured electric power of each electric power generating apparatus in accordance with a difference between a total of the procured electric power or a total of the amount of procured electric power and the desired electric power for purchase or the desired amount of electric power for purchase and the calculated ratio of each electric power generating apparatus.

7. The electric power control apparatus according to 3,

in which the supply-demand adjusting unit decides a combination of electric power generating apparatuses in which a difference between a total of the procured electric power or a total of the amount of procured electric power and the desired electric power for purchase or the desired amount of electric power for purchase is less than or equal to a predetermined reference, on the basis of a level of prediction accuracy related to electric power generation of each electric power generating apparatus.

8. The electric power control apparatus according to 1, further including

a supply-demand adjusting unit that adjusts a balance between the procured electric power or the amount of procured electric power in the electric power procurement information and the desired electric power for purchase or the desired amount of electric power for purchase in the desired purchase information on the basis of the comparison data,

in which in a case where the procured electric power or the amount of procured electric power in the electric power procurement information is larger than the desired electric power for purchase or the desired amount of electric power for purchase in the desired purchase information, the supply-demand adjusting unit refers to a list storing an electric power storage apparatus that can be controlled for adjusting the balance, and increases the desired electric power for purchase or the desired amount of electric power for purchase in the desired purchase information by increasing scheduled charging electric power or an amount of scheduled charging electric power of at least one electric power storage apparatus included in the list during the period.

9. The electric power control apparatus according to 8,

in which the supply-demand adjusting unit decides an increase amount in the scheduled charging electric power or the amount of scheduled charging electric power of each electric power storage apparatus on the basis of a chargeability or a free capacity of the electric power storage apparatus.

10. The electric power control apparatus according to 9,

in which the supply-demand adjusting unit repeatedly selects an electric power storage apparatus of which the scheduled charging electric power or the amount of scheduled charging electric power is to be increased, in descending order of the chargeability or the free capacity until a difference between the desired electric power for purchase or the desired amount of electric power for purchase and the procured electric power or the amount of procured electric power becomes less than or equal to a predetermined reference.

11. The electric power control apparatus according to 9,

in which the supply-demand adjusting unit
calculates a ratio of each electric power storage apparatus using the chargeability or the free capacity of each electric power storage apparatus, and
decides the increase amount in the scheduled charging electric power or the amount of scheduled charging electric power of each electric power storage apparatus in accordance with a difference between the desired electric power for purchase or the desired amount of electric power for purchase and the procured electric power or the amount of procured electric power and the calculated ratio of each electric power generating apparatus.

12. The electric power control apparatus according to 1, further including

a supply-demand adjusting unit that adjusts a balance between the procured electric power or the amount of procured electric power in the electric power procurement information and the desired electric power for purchase or the desired amount of electric power for purchase in the desired purchase information on the basis of the comparison data,

in which in a case where the desired electric power for purchase or the desired amount of electric power for purchase in the desired purchase information is larger than the procured electric power or the amount of procured electric power in the electric power procurement information, the supply-demand adjusting unit decreases the desired electric power for purchase or the desired amount of electric power for purchase in the desired purchase information by adjusting an amount of electric power to be sold to each consumer using attribute information of each consumer.

13. The electric power control apparatus according to 1,

in which the sales information includes information related to a selling price of electric power, and

the desired purchase information collecting unit
acquires the comparison data and calculates a difference value between the procured electric power or the amount of procured electric power in the electric power procurement information and the desired electric power for purchase or the desired amount of electric power for purchase in the desired purchase information,
transmits a corrected selling price of electric power included in the sales information to the terminal of the consumer again in a case where the difference value does not satisfy a reference, and
ends receiving the desired purchase information in a case where the difference value satisfies the reference.

14. The electric power control apparatus according to any one of 1 to 13,

in which the electric power procurement information deciding unit
acquires the predicted electric power generation output and past electric power generation record information of the electric power generating apparatus,
calculates prediction accuracy for an electric power generation prediction value at each time on the basis of the past electric power generation record information,
decides an electric power value for calculation of procured electric power at each time on the basis of the electric power generation prediction value and the prediction accuracy at each time, and
decides an amount of electric power acquired by integrating the procured electric power in the period with respect to time as the amount of procured electric power,
in which the procured electric power is a difference between the electric power value for calculation of procured electric power at each time and the upper limit output value.

15. The electric power control apparatus according to 14,

in which the electric power procurement information deciding unit sets the electric power value for calculation of procured electric power to have a value closer to the electric power generation prediction value as the prediction accuracy is increased.

16. An electric power control method executed by a computer, including:

deciding electric power procurement information using a predicted electric power generation output of an electric power generating apparatus and control instruction information which includes a period in which an output of the electric power generating apparatus is controlled and an upper limit output value thereof, the electric power procurement information indicating procured electric power or an amount of procured electric power acquired from a difference between the predicted electric power generation output during the period and the upper limit output value;

transmitting sales information related to the procured electric power or the amount of procured electric power in the electric power procurement information to a terminal of a consumer, and collecting desired purchase information indicating desired electric power for purchase or a desired amount of electric power for purchase with respect to the procured electric power or the amount of procured electric power in the electric power procurement information; and

outputting comparison data for comparing the electric power procurement information with the desired purchase information.

17. The electric power control method executed by the computer according to 16, the method further including

a process step of adjusting a balance between the procured electric power or the amount of procured electric power in the electric power procurement information and the desired electric power for purchase or the desired amount of electric power for purchase in the desired purchase information on the basis of the comparison data,

in which in the process step, in a case where the procured electric power or the amount of procured electric power in the electric power procurement information is larger than the desired electric power for purchase or the desired amount of electric power for purchase in the desired purchase information, the procured electric power or the amount of procured electric power in the electric power procurement information to the desired electric power for purchase or the desired amount of electric power for purchase in the desired purchase information is decreased.

18. The electric power control method executed by the computer according to 17, the method further including

decreasing the whole procured electric power or the whole amount of procured electric power by adjusting the procured electric power or the amount of procured electric power of each electric power generating apparatus using attribute information of each electric power generating apparatus.

19. The electric power control method executed by the computer according to 18, the method further including:

calculating a ratio of each electric power generating apparatus using the predicted electric power generation output of each electric power generating apparatus; and

deciding a change amount in the procured electric power or the amount of procured electric power of each electric power generating apparatus in accordance with a difference between a total of the procured electric power or a total of the amount of procured electric power and the desired electric power for purchase or the desired amount of electric power for purchase and the calculated ratio of each electric power generating apparatus.

20. The electric power control method executed by the computer according to 18, the method further including

deciding a combination of electric power generating apparatuses in which a difference between a total of the procured electric power or a total of the amount of procured electric power and the desired electric power for purchase or the desired amount of electric power for purchase is less than or equal to a predetermined reference, on the basis of a magnitude of the predicted electric power generation output of each electric power generating apparatus.

21. The electric power control method executed by the computer according to 18, the method further including:

calculating a ratio of each electric power generating apparatus using prediction accuracy related to electric power generation of each electric power generating apparatus; and

deciding a change amount in the procured electric power or the amount of procured electric power of each electric power generating apparatus in accordance with a difference between a total of the procured electric power or a total of the amount of procured electric power and the desired electric power for purchase or the desired amount of electric power for purchase and the calculated ratio of each electric power generating apparatus.

22. The electric power control method executed by the computer according to 18, the method further including

deciding a combination of electric power generating apparatuses in which a difference between a total of the procured electric power or a total of the amount of procured electric power and the desired electric power for purchase or the desired amount of electric power for purchase is less than or equal to a predetermined reference, on the basis of a level of prediction accuracy related to electric power generation of each electric power generating apparatus.

23. The electric power control method executed by the computer according to 16, the method further including

a process step of adjusting a balance between the procured electric power or the amount of procured electric power in the electric power procurement information and the desired electric power for purchase or the desired amount of electric power for purchase in the desired purchase information on the basis of the comparison data,

in which in the process step, in a case where the procured electric power or the amount of procured electric power in the electric power procurement information is larger than the desired electric power for purchase or the desired amount of electric power for purchase in the desired purchase information, a list storing an electric power storage apparatus that can be controlled for adjusting the balance, and increases the desired electric power for purchase or the desired amount of electric power for purchase in the desired purchase information by increasing scheduled charging electric power or an amount of scheduled charging electric power of at least one electric power storage apparatus included in the list during the period is referred to.

24. The electric power control method executed by the computer according to 23, the method further including

deciding an increase amount in the scheduled charging electric power or the amount of scheduled charging electric power of each electric power storage apparatus on the basis of a chargeability or a free capacity of the electric power storage apparatus.

25. The electric power control method executed by the computer according to 24, the method further including

repeatedly selecting an electric power storage apparatus of which the scheduled charging electric power or the amount of scheduled charging electric power is to be increased, in descending order of the chargeability or the free capacity until a difference between the desired electric power for purchase or the desired amount of electric power for purchase and the procured electric power or the amount of procured electric power becomes less than or equal to a predetermined reference.

26. The electric power control method executed by the computer according to 24, the method further including:

calculating a ratio of each electric power storage apparatus using the chargeability or the free capacity of each electric power storage apparatus; and

deciding the increase amount in the scheduled charging electric power or the amount of scheduled charging electric power of each electric power storage apparatus in accordance with a difference between the desired electric power for purchase or the desired amount of electric power for purchase and the procured electric power or the amount of procured electric power and the calculated ratio of each electric power generating apparatus.

27. The electric power control method executed by the computer according to 16, the method further including

a process step of adjusting a balance between the procured electric power or the amount of procured electric power in the electric power procurement information and the desired electric power for purchase or the desired amount of electric power for purchase in the desired purchase information on the basis of the comparison data,

in which in the process step, in a case where the desired electric power for purchase or the desired amount of electric power for purchase in the desired purchase information is larger than the procured electric power or the amount of procured electric power in the electric power procurement information, the desired electric power for purchase or the desired amount of electric power for purchase in the desired purchase information by adjusting an amount of electric power to be sold to each consumer using attribute information of each consumer is decreased.

28. The electric power control method executed by the computer according to 16,

in which the sales information includes information related to a selling price of electric power,

the method further including:

acquiring the comparison data and calculates a difference value between the procured electric power or the amount of procured electric power in the electric power procurement information and the desired electric power for purchase or the desired amount of electric power for purchase in the desired purchase information,

transmitting a corrected selling price of electric power included in the sales information to the terminal of the consumer again in a case where the difference value does not satisfy a reference, and

ending receiving the desired purchase information in a case where the difference value satisfies the reference.

29. The electric power control method executed by the computer according to any one of 16 to 28, the method further including:

acquiring the predicted electric power generation output and past electric power generation record information of the electric power generating apparatus;

calculating prediction accuracy for an electric power generation prediction value at each time on the basis of the past electric power generation record information;

deciding an electric power value for calculation of procured electric power at each time on the basis of the electric power generation prediction value and the prediction accuracy at each time; and

deciding an amount of electric power acquired by integrating the procured electric power in the period with respect to time as the amount of procured electric power,

in which the procured electric power is a difference between the electric power value for calculation of procured electric power at each time and the upper limit output value.

30. The electric power control method executed by the computer according to 29, the method further including

setting the electric power value for calculation of procured electric power to have a value closer to the electric power generation prediction value as the prediction accuracy is increased.

31. A program causing a computer to function as:

an electric power procurement information deciding unit that decides electric power procurement information using a predicted electric power generation output of an electric power generating apparatus and control instruction information which includes a period in which an output of the electric power generating apparatus is controlled and an upper limit output value thereof, the electric power procurement information indicating procured electric power or an amount of procured electric power acquired from a difference between the predicted electric power generation output during the period and the upper limit output value;

a desired purchase information collecting unit that transmits sales information related to the procured electric power or the amount of procured electric power in the electric power procurement information to a terminal of a consumer, and collects desired purchase information indicating desired electric power for purchase or a desired amount of electric power for purchase with respect to the procured electric power or the amount of procured electric power in the electric power procurement information; and

a comparison data output unit that outputs comparison data for comparing the electric power procurement information with the desired purchase information.

32. The program according to 31, causing the computer to further function as

a supply-demand adjusting unit that adjusts a balance between the procured electric power or the amount of procured electric power in the electric power procurement information and the desired electric power for purchase or the desired amount of electric power for purchase in the desired purchase information on the basis of the comparison data,

in which in a case where the procured electric power or the amount of procured electric power in the electric power procurement information is larger than the desired electric power for purchase or the desired amount of electric power for purchase in the desired purchase information, the supply-demand adjusting unit decreases the procured electric power or the amount of procured electric power in the electric power procurement information to the desired electric power for purchase or the desired amount of electric power for purchase in the desired purchase information.

33. The program according to 32, causing the computer to further function as

a unit that decreases the whole procured electric power or the whole amount of procured electric power by adjusting the procured electric power or the amount of procured electric power of each electric power generating apparatus using attribute information of each electric power generating apparatus.

34. The program according to 33, causing the computer to further function as a unit that

calculates a ratio of each electric power generating apparatus using the predicted electric power generation output of each electric power generating apparatus, and

decides a change amount in the procured electric power or the amount of procured electric power of each electric power generating apparatus in accordance with a difference between a total of the procured electric power or a total of the amount of procured electric power and the desired electric power for purchase or the desired amount of electric power for purchase and the calculated ratio of each electric power generating apparatus.

35. The program according to 33, causing the computer to further function as

a unit that decides a combination of electric power generating apparatuses in which a difference between a total of the procured electric power or a total of the amount of procured electric power and the desired electric power for purchase or the desired amount of electric power for purchase is less than or equal to a predetermined reference, on the basis of a magnitude of the predicted electric power generation output of each electric power generating apparatus.

36. The program according to 33, causing the computer to further function as a unit that

calculates a ratio of each electric power generating apparatus using prediction accuracy related to electric power generation of each electric power generating apparatus, and

decides a change amount in the procured electric power or the amount of procured electric power of each electric power generating apparatus in accordance with a difference between a total of the procured electric power or a total of the amount of procured electric power and the desired electric power for purchase or the desired amount of electric power for purchase and the calculated ratio of each electric power generating apparatus.

37. The program according to 33, causing the computer to further function as

a unit that decides a combination of electric power generating apparatuses in which a difference between a total of the procured electric power or a total of the amount of procured electric power and the desired electric power for purchase or the desired amount of electric power for purchase is less than or equal to a predetermined reference, on the basis of a level of prediction accuracy related to electric power generation of each electric power generating apparatus.

38. The program according to 31, causing the computer to further function as

a supply-demand adjusting unit that adjusts a balance between the procured electric power or the amount of procured electric power in the electric power procurement information and the desired electric power for purchase or the desired amount of electric power for purchase in the desired purchase information on the basis of the comparison data,

in which in a case where the procured electric power or the amount of procured electric power in the electric power procurement information is larger than the desired electric power for purchase or the desired amount of electric power for purchase in the desired purchase information, the supply-demand adjusting unit refers to a list storing an electric power storage apparatus that can be controlled for adjusting the balance, and increases the desired electric power for purchase or the desired amount of electric power for purchase in the desired purchase information by increasing scheduled charging electric power or an amount of scheduled charging electric power of at least one electric power storage apparatus included in the list during the period.

39. The program according to 38, causing the computer to further function as

a unit that decides an increase amount in the scheduled charging electric power or the amount of scheduled charging electric power of each electric power storage apparatus on the basis of a chargeability or a free capacity of the electric power storage apparatus.

40. The program according to 39, causing the computer to further function as

a unit that repeatedly selects an electric power storage apparatus of which the scheduled charging electric power or the amount of scheduled charging electric power is to be increased, in descending order of the chargeability or the free capacity until a difference between the desired electric power for purchase or the desired amount of electric power for purchase and the procured electric power or the amount of procured electric power becomes less than or equal to a predetermined reference.

41. The program according to 39, causing the computer to further function as a unit that

calculates a ratio of each electric power storage apparatus using the chargeability or the free capacity of each electric power storage apparatus, and

decides the increase amount in the scheduled charging electric power or the amount of scheduled charging electric power of each electric power storage apparatus in accordance with a difference between the desired electric power for purchase or the desired amount of electric power for purchase and the procured electric power or the amount of procured electric power and the calculated ratio of each electric power generating apparatus.

42. The program according to 31, causing the computer to further function as

a supply-demand adjusting unit that adjusts a balance between the procured electric power or the amount of procured electric power in the electric power procurement information and the desired electric power for purchase or the desired amount of electric power for purchase in the desired purchase information on the basis of the comparison data,

in which in a case where the desired electric power for purchase or the desired amount of electric power for purchase in the desired purchase information is larger than the procured electric power or the amount of procured electric power in the electric power procurement information, the supply-demand adjusting unit decreases the desired electric power for purchase or the desired amount of electric power for purchase in the desired purchase information by adjusting an amount of electric power to be sold to each consumer using attribute information of each consumer.

43. The program according to 31,

in which the sales information includes information related to a selling price of electric power,

the program causing a computer to further function as a unit that

acquires the comparison data and calculates a difference value between the procured electric power or the amount of procured electric power in the electric power procurement information and the desired electric power for purchase or the desired amount of electric power for purchase in the desired purchase information,

transmits a corrected selling price of electric power included in the sales information to the terminal of the consumer again in a case where the difference value does not satisfy a reference, and

ends receiving the desired purchase information in a case where the difference value satisfies the reference.

44. The program according to any one of 31 to 43, causing the computer to further function as a unit that

acquires the predicted electric power generation output and past electric power generation record information of the electric power generating apparatus,

calculates prediction accuracy for an electric power generation prediction value at each time on the basis of the past electric power generation record information,

decides an electric power value for calculation of procured electric power at each time on the basis of the electric power generation prediction value and the prediction accuracy at each time, and

decides an amount of electric power acquired by integrating the procured electric power in the period with respect to time as the amount of procured electric power,

in which the procured electric power is a difference between the electric power value for calculation of procured electric power at each time and the upper limit output value.

45. The program according to 44, causing the computer to further function as

a unit that sets the electric power value for calculation of procured electric power to have a value closer to the electric power generation prediction value as the prediction accuracy is increased.

This application claims the benefit of priority from Japanese Patent Application No. 2016-072087 filed on Mar. 31, 2016, the entire disclosure of which is incorporated herein.

1. An electric power control apparatus comprising:
a memory storing instructions; and
a processor configured to execute the instructions to:
decide electric power procurement information using a predicted electric power generation output of an electric power generating apparatus and control instruction information which includes a period in which an output of the electric power generating apparatus is controlled and an upper limit output value thereof, the electric power procurement information indicating procured electric power or an amount of procured electric power acquired from a difference between the predicted electric power generation output during the period and the upper limit output value;
transmit sales information related to the procured electric power or the amount of procured electric power in the electric power procurement information to a terminal of a consumer, and collects desired purchase information indicating desired electric power for purchase or a desired amount of electric power for purchase with respect to the procured electric power or the amount of procured electric power in the electric power procurement information; and
output comparison data for comparing the electric power procurement information with the desired purchase information.

2. The electric power control apparatus according to claim 1, wherein the processor is further configured to:
adjust a balance between the procured electric power or the amount of procured electric power in the electric power procurement information and the desired electric power for purchase or the desired amount of electric power for purchase in the desired purchase information on the basis of the comparison data; and
in a case where the procured electric power or the amount of procured electric power in the electric power procurement information is larger than the desired electric power for purchase or the desired amount of electric power for purchase in the desired purchase information, decrease the procured electric power or the amount of procured electric power in the electric power procurement information to the desired electric power for purchase or the desired amount of electric power for purchase in the desired purchase information.

3. The electric power control apparatus according to claim 2,
wherein the processor is further configured to decrease the whole procured electric power or the whole amount of procured electric power by adjusting the procured electric power or the amount of procured electric power of each electric power generating apparatus using attribute information of each electric power generating apparatus.

4. The electric power control apparatus according to claim 3,
wherein the processor is further configured to:
calculate a ratio of each electric power generating apparatus using the predicted electric power generation output of each electric power generating apparatus; and
decide a change amount in the procured electric power or the amount of procured electric power of each electric power generating apparatus in accordance with a difference between a total of the procured electric power or a total of the amount of procured electric power and the desired electric power for purchase or the desired amount of electric power for purchase and the calculated ratio of each electric power generating apparatus.

5. The electric power control apparatus according to claim 3,
wherein the processor is further configured to execute the instructions to decide a combination of electric power generating apparatuses in which a difference between a total of the procured electric power or a total of the amount of procured electric power and the desired electric power for purchase or the desired amount of electric power for purchase is less than or equal to a predetermined reference, on the basis of a magnitude of the predicted electric power generation output of each electric power generating apparatus.

6. The electric power control apparatus according to claim 3,
wherein the processor is further configured to:
calculate a ratio of each electric power generating apparatus using prediction accuracy related to electric power generation of each electric power generating apparatus; and
decide a change amount in the procured electric power or the amount of procured electric power of each electric power generating apparatus in accordance with a difference between a total of the procured electric power or a total of the amount of procured electric power and the desired electric power for purchase or the desired amount of electric power for purchase and the calculated ratio of each electric power generating apparatus.

7. The electric power control apparatus according to claim 3,
wherein the processor is further configured to decide a combination of electric power generating apparatuses in which a difference between a total of the procured electric power or a total of the amount of procured electric power and the desired electric power for purchase or the desired amount of electric power for purchase is less than or equal to a predetermined reference, on the basis of a level of prediction accuracy related to electric power generation of each electric power generating apparatus.

8. The electric power control apparatus according to claim 1, wherein the processor is further configured to:
adjust a balance between the procured electric power or the amount of procured electric power in the electric power procurement information and the desired electric power for purchase or the desired amount of electric power for purchase in the desired purchase information on the basis of the comparison data; and
in a case where the procured electric power or the amount of procured electric power in the electric power procurement information is larger than the desired electric power for purchase or the desired amount of electric power for purchase in the desired purchase information, refer to a list storing an electric power storage apparatus that can be controlled for adjusting the balance, and increases the desired electric power for purchase or the desired amount of electric power for purchase in the desired purchase information by increasing scheduled charging electric power or an amount of scheduled charging electric power of at least one electric power storage apparatus included in the list during the period.

9. The electric power control apparatus according to claim 8,
wherein the processor is further configured to decide an increase amount in the scheduled charging electric power or the amount of scheduled charging electric power of each electric power storage apparatus on the basis of a chargeability or a free capacity of the electric power storage apparatus.

10. The electric power control apparatus according to claim 9,
wherein the processor is further configured to repeatedly select an electric power storage apparatus of which the scheduled charging electric power or the amount of scheduled charging electric power is to be increased, in descending order of the chargeability or the free capacity until a difference between the desired electric power for purchase or the desired amount of electric power for purchase and the procured electric power or the amount of procured electric power becomes less than or equal to a predetermined reference.

11. The electric power control apparatus according to claim 9,
wherein the processor is further configured to:
calculate a ratio of each electric power storage apparatus using the chargeability or the free capacity of each electric power storage apparatus; and
decide the increase amount in the scheduled charging electric power or the amount of scheduled charging electric power of each electric power storage apparatus in accordance with a difference between the desired electric power for purchase or the desired amount of electric power for purchase and the procured electric power or the amount of procured electric power and the calculated ratio of each electric power generating apparatus.

12. The electric power control apparatus according to claim 1, wherein the processor is further configured to:
adjust a balance between the procured electric power or the amount of procured electric power in the electric power procurement information and the desired electric power for purchase or the desired amount of electric power for purchase in the desired purchase information on the basis of the comparison data; and
in a case where the desired electric power for purchase or the desired amount of electric power for purchase in the desired purchase information is larger than the procured electric power or the amount of procured electric power in the electric power procurement information, decrease the desired electric power for purchase or the desired amount of electric power for purchase in the desired purchase information by adjusting an amount of electric power to be sold to each consumer using attribute information of each consumer.

13. The electric power control apparatus according to claim 1,
wherein the sales information includes information related to a selling price of electric power, and
the processor is further configured to:
acquire the comparison data and calculates a difference value between the procured electric power or the amount of procured electric power in the electric power procurement information and the desired electric power for purchase or the desired amount of electric power for purchase in the desired purchase information;
transmit a corrected selling price of electric power included in the sales information to the terminal of the consumer again in a case where the difference value does not satisfy a reference; and
end receiving the desired purchase information in a case where the difference value satisfies the reference.

14. The electric power control apparatus according to claim 1,
wherein the processor is further configured to:
acquire the predicted electric power generation output and past electric power generation record information of the electric power generating apparatus;
calculate prediction accuracy for an electric power generation prediction value at each time on the basis of the past electric power generation record information;
decide an electric power value for calculation of procured electric power at each time on the basis of the electric power generation prediction value and the prediction accuracy at each time; and
decide an amount of electric power acquired by integrating the procured electric power in the period with respect to time as the amount of procured electric power,
wherein the procured electric power is a difference between the electric power value for calculation of procured electric power at each time and the upper limit output value.

15. The electric power control apparatus according to claim 14,
wherein the processor is further configured to set the electric power value for calculation of procured electric power to have a value closer to the electric power generation prediction value as the prediction accuracy is increased.

16. An electric power control method executed by a computer, comprising:
deciding electric power procurement information using a predicted electric power generation output of an electric power generating apparatus and control instruction information which includes a period in which an output of the electric power generating apparatus is controlled and an upper limit output value thereof, the electric power procurement information indicating procured electric power or an amount of procured electric power acquired from a difference between the predicted electric power generation output during the period and the upper limit output value;
transmitting sales information related to the procured electric power or the amount of procured electric power in the electric power procurement information to a terminal of a consumer, and collecting desired purchase information indicating desired electric power for purchase or a desired amount of electric power for purchase with respect to the procured electric power or the amount of procured electric power in the electric power procurement information; and
outputting comparison data for comparing the electric power procurement information with the desired purchase information.

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. A non-transitory computer readable medium storing a program causing a computer to execute a method, the method comprising:
decide electric power procurement information using a predicted electric power generation output of an electric power generating apparatus and control instruction information which includes a period in which an output of the electric power generating apparatus is controlled and an upper limit output value thereof, the electric power procurement information indicating procured electric power or an amount of procured electric power acquired from a difference between the predicted electric power generation output during the period and the upper limit output value;
transmit sales information related to the procured electric power or the amount of procured electric power in the electric power procurement information to a terminal of a consumer, and collects desired purchase information indicating desired electric power for purchase or a desired amount of electric power for purchase with respect to the procured electric power or the amount of procured electric power in the electric power procurement information; and
output comparison data for comparing the electric power procurement information with the desired purchase information.

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)
